(19) United States
(12) Patent Application Publication
(10) Pub. No.: US 2025/0089233 A1
(43) Pub. Date: Mar. 13, 2025

(54) NITRIDE LATTICE SUPPORT IN MEMORY

(71) Applicant: Micron Technology, Inc., Boise, ID (US)

(72) Inventor: Yongjun J. Hu, Boise, ID (US)

(21) Appl. No.: 18/784,176

(22) Filed: Jul. 25, 2024

Related U.S. Application Data
(60) Provisional application No. 63/537,928, filed on Sep. 12, 2023.

(51) Int. Cl. H10B 12/00

(52) U.S. Cl. CPC H10B 12/05; H10B 12/30

(57) ABSTRACT

Systems, methods and apparatus are provided for nitride lattice support structures and double side capacitors in vertical three-dimensional (3D) memory. An example method includes a method for forming a nitride lattice support structures for an array of vertically stacked memory cells having access devices and storage nodes. The method includes depositing alternating layers of a channel material and a first sacrificial material in repeating iterations to form a vertical stack on a substrate. The vertical stack can be patterned to form a plurality of elongated vertical columns separated by a plurality of first vertical opening. A second sacrificial material can be deposited to fill the first vertical openings and cover the vertical stack. A plurality of vertical openings and lateral recesses can be formed. A nitride material can be deposited in the vertical openings and lateral recesses to form a plurality of nitride lattice support structures.

### PRIORITY INFORMATION

This application claims the benefit of U.S. Provisional Application No. 63/537,928, filed on Sep. 12, 2023, the contents of which are incorporated herein by reference.

### TECHNICAL FIELD

The present disclosure relates generally to memory devices, and more particularly, to nitride lattice support structures and double side capacitors for vertical three-dimensional (3D) memory.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, (e.g., a transistor) having a first and a second source/drain regions separated by a channel region. A gate may oppose the channel region and be separated therefrom by a gate dielectric. An access line, such as a word line, is electrically connected to the gate of the DRAM cell. A DRAM cell can include a storage node, such as a capacitor cell, coupled by the access device to a digit line. The access device can be activated (e.g., to select the cell) by an access line coupled to the access transistor. The capacitor can store a charge corresponding to a data value of a respective cell (e.g., a logic “1” or “0”).

### BRIEF DESCRIPTION OF THE DRAWINGS

FIG. 1A is a schematic illustration of a vertical three dimensional (3D) memory in accordance with a number of embodiments of the present disclosure.

FIG. 1B is a perspective view illustrating a portion of a vertical three dimensional (3D) memory in accordance with a number of embodiments of the present disclosure.

FIG. 2 illustrates an example method, at one stage of a semiconductor fabrication process, for forming a nitride lattice support structure in memory in accordance with a number of embodiments of the present disclosure.

FIGS. 3A to 3C each illustrate an example method, at another stage of a semiconductor fabrication process, for forming a nitride lattice support in memory, in accordance with a number of embodiments of the present disclosure.

FIGS. 4A to 4C each illustrate an example method, at another stage of a semiconductor fabrication process, for forming a nitride lattice support in memory, in accordance with a number of embodiments of the present disclosure.

FIGS. 5A to 5E each illustrate an example method, at another stage of a semiconductor fabrication process, for forming a nitride lattice support in memory, in accordance with a number of embodiments of the present disclosure.

FIGS. 6A to 6B each illustrate an example method, at another stage of a semiconductor fabrication process, for forming a nitride lattice support in memory, in accordance with a number of embodiments of the present disclosure.

FIGS. 7A to 7C each illustrate an example method, at another stage of a semiconductor fabrication process, for forming a nitride lattice support in memory, in accordance with a number of embodiments of the present disclosure.

FIGS. 8A to 8E each illustrate an example method, at another stage of a semiconductor fabrication process, for forming a nitride lattice support in memory, in accordance with a number of embodiments of the present disclosure.

FIGS. 9A to 9D each illustrate an example method, at another stage of a semiconductor fabrication process, for forming a nitride lattice support in memory, in accordance with a number of embodiments of the present disclosure.

FIGS. 10A to 9C each illustrate an example method, at another stage of a semiconductor fabrication process, for forming a nitride lattice support in memory, in accordance with a number of embodiments of the present disclosure.

FIGS. 11A to 11B each illustrate an example method, at another stage of a semiconductor fabrication process, for forming a nitride lattice support in memory, in accordance with a number of embodiments of the present disclosure.

FIGS. 12A to 12B each illustrate an example method, at another stage of a semiconductor fabrication process, for forming a nitride lattice support in memory, in accordance with a number of embodiments of the present disclosure.

FIGS. 13A to 13C each illustrate an example method, at another stage of a semiconductor fabrication process, for forming a nitride lattice support in memory, in accordance with a number of embodiments of the present disclosure.

FIGS. 14A to 14B each illustrate an example method, at another stage of a semiconductor fabrication process, for forming a nitride lattice support in memory, in accordance with a number of embodiments of the present disclosure.

FIGS. 15A to 15B each illustrate an example method, at another stage of a semiconductor fabrication process, for forming a nitride lattice support in memory, in accordance with a number of embodiments of the present disclosure.

FIGS. 16A to 16B each illustrate an example method, at another stage of a semiconductor fabrication process, for forming a nitride lattice support in memory, in accordance with a number of embodiments of the present disclosure.

FIGS. 17A to 17B each illustrate an example method, at another stage of a semiconductor fabrication process, for forming a nitride lattice support in memory, in accordance with a number of embodiments of the present disclosure.

FIGS. 18A to 18C each illustrate an example method, at another stage of a semiconductor fabrication process, for forming a nitride lattice support in memory, in accordance with a number of embodiments of the present disclosure.

FIG. 19 is a block diagram of an apparatus in the form of a computing system including a memory device in accordance with a number of embodiments of the present disclosure.

### DETAILED DESCRIPTION

Embodiments of the present disclosure describe nitride lattice support structures and double side capacitors for vertical three-dimensional (3D) memory. Nitride lattice support structures may be formed in a second vertical opening to provide support to pillar columns and additional access to storage nodes. As an example, the nitride lattice support structures may mitigate and/or prevent wobbling and/or buckling of the pillar columns when increasing the height of the pillar columns. Additionally, the nitride lattice support structures may enable the formation of double sided capacitors in vertical 3D memory. As an example, the nitride lattice support structures may provide access that can allow for the deposition of conductive material on either side of the bottom electrode of a capacitor. The embodiments described herein may achieve vertical stacks with a reduced size and capacitor cells with an increased area and reduced length, as compared to previous approaches that include vertical stacks and capacitor cells formed with a reduced pillar column height.

For example, embodiments described herein may include method, systems, and apparatus for forming arrays of vertically stacked memory cells, having horizontally oriented access devices and horizontally oriented storage nodes. The method includes depositing alternating layers of a channel material and a sacrificial material in repeating iterations to form a vertical stack. A plurality of spaced, first vertical openings are formed through the vertical stack adjacent areas where storage nodes will be formed. A first oxide material can be deposited to cover the array and fill the first vertical openings. A plurality of second vertical openings are formed through the first oxide material, extending laterally across the first vertical openings. A plurality of third vertical openings are formed, extending from the first vertical openings and extending through the first vertical openings. The third vertical openings extend from a first pair of second vertical openings through every other first vertical opening, and the third vertical openings extend from a second pair of second vertical openings through every first vertical opening. The sacrificial material can be etched a first lateral distance from the third vertical openings. A nitride lattice material can be deposited in the plurality of second vertical openings and third vertical openings to form a plurality of nitride lattice support structures. The first oxide material can be selectively etched to uncover the array and reopen the plurality of first vertical openings. The sacrificial material can be selectively etched to form a plurality of first horizontal openings and leaving a plurality of channel material channels supported by the nitride lattice support structure.

In some embodiments, a layer of the nitride lattice material can be deposited to form a nitride moat wall connecting and supporting the plurality of nitride lattice support structures. In some embodiments, a pair of the nitride lattice support structures allow access through the nitride lattice support structure while supporting the array. As an example, additional material may be added to or removed from the array during formation of the memory device through the nitride lattice support structure that may not be possible with prior approaches of forming the structure, such as replacement of an oxide material surrounding a capacitor bottom electrode with a conductive material to form a double sided capacitor. Advantages of the nitride lattice support structures and double sided capacitor structures and process described herein can include reduced capacitor length while maintaining sufficient capacitance, in addition to support of three-dimensional (3D) memory devices.

In some example embodiments, forming a nitride lattice support structure for an array of vertically stacked memory cells having access devices and storage nodes may include depositing alternating layers of a channel material and a first sacrificial material in repeating iterations to form a vertical stack on a substrate. The vertical stack may then be patterned to form a plurality of elongated vertical columns having first sidewalls and separated by a plurality of first vertical openings extending predominantly in a first horizontal direction. A second sacrificial material may be deposited to fill the first vertical openings and cover the vertical stack. A plurality of second vertical openings can be formed through the second sacrificial material, extending predominantly in the first lateral direction across the plurality of first vertical openings. A plurality of third vertical openings may then be formed extending from each second vertical opening through the second sacrificial material filling the first vertical openings to the substrate to partially expose the first sidewalls of the alternating layers. The first sacrificial material may be selectively etched a first lateral distance back from the plurality third vertical openings to form a plurality of first lateral recesses, and a nitride material (e.g., Si₃N₄) may be deposited to form a plurality of nitride lattice support structures by filling the plurality of second vertical openings, the plurality of third vertical openings, and the plurality of first lateral recesses.

In some example embodiments, the vertical stack may be patterned by forming a plurality of spaced, first vertical openings through the vertical stack to define elongated vertical columns adjacent areas where storage nodes will be formed, with first sidewalls of the alternating layers, the columns having a first lateral direction and a first horizontal direction and extending primarily in the first horizontal direction.

In some example embodiments, depositing a second sacrificial material to cover the vertical stack can include depositing a first oxide material to cover the array and fill the first vertical openings. In some example embodiments, the channel material can be a silicon material. In some example embodiments, the first sacrificial material can be a silicon germanium material.

In some example embodiments, the first lateral distance can be half of a lateral width of an elongated vertical column of the plurality of elongated vertical columns such that the two first lateral recesses are equivalent to the lateral width of an elongated vertical column.

In some example embodiments, the third vertical openings can extend through alternating occurrences of first vertical openings of the plurality of first vertical openings intersected by a first pair of second vertical openings, and the first pair of second vertical openings horizontally disposed adjacent to opposing sides of a storage node electrode exit area. The third vertical openings can extend through each occurrence of a first vertical opening of the plurality of first vertical openings that are intersected by a second pair of second vertical openings, and the second pair of second vertical openings horizontally disposed adjacent opposing sides of where an access device will be formed.

Some example embodiments can also include selectively etching the second sacrificial material to uncover the array and reopen the plurality of first vertical openings. The first sacrificial material can then be selectively etched to form a plurality of first horizontal openings to define a plurality of channel material channels supported by the plurality of nitride lattice support structures and extending predominantly in the first horizontal direction.

Some example embodiments can also include depositing a layer of nitride material on the stacked memory cells to form a nitride well wall, connecting the plurality of nitride lattice support structures.

In some example embodiments, forming an array of vertically stacked memory cells having double sided capacitors, access devices, and storage nodes, can include depositing and patterning alternating layers of a channel material and a first sacrificial material in repeating iterations to form a plurality of elongated vertical columns having first sidewalls and separated by a plurality of first vertical openings extending predominantly in a first horizontal direction. A second sacrificial material can be deposited to cover the vertical stack and fill the first vertical openings. A plurality of second vertical openings can be formed through the second sacrificial material, across the plurality of first vertical openings. A plurality of third vertical openings can then be formed extending predominantly in the first vertical direction, from each second vertical opening, through a plurality of the first vertical openings. The first sacrificial material may be selectively etched a first lateral distance back from the plurality third vertical openings to form a plurality of first lateral recesses. A nitride material may then be deposited to form a plurality of nitride lattice support structures. The first sacrificial material and the second sacrificial material may be selectively removed to form a plurality of channel material channels. An access device can be formed between a second pair of nitride lattice support structures, of the plurality of nitride lattice support structures. Additional nitride material can be deposited to form a nitride well wall, disposed on and coupled to the plurality of nitride lattice support structures, and a plurality of storage nodes can be formed between the first pair of nitride lattice support structures and a second pair of nitride lattice support structures, of the plurality of nitride lattice support structures.

In some example embodiments, depositing and patterning alternating layers of a channel material and a first sacrificial material can includes depositing alternating layers of a channel material and a sacrificial material in repeating iterations to form a vertical stack. A plurality of spaced first vertical openings can then be formed through the vertical stack to define a plurality of elongated vertical columns, with first sidewalls of the alternating layers, the columns having a first lateral direction and a first horizontal direction and extending primarily in the first horizontal direction.

In some example embodiments, forming a plurality of second openings and forming a plurality of third openings includes forming the plurality of second vertical openings through the second sacrificial material, extending predominantly in the first lateral direction, and a plurality of third vertical openings, extending predominantly in the first vertical direction, extending from a second vertical opening, of the plurality of second vertical opening, and extending through a first vertical opening, of the plurality of first vertical openings, to partially expose the first sidewalls of the alternating layers. The third vertical openings can extend through every other first vertical opening, of the plurality of first vertical openings intersected by a first pair of second vertical openings, the first pair of second vertical openings adjacent, and on either side of a storage node electrode exit area and the third vertical openings can extend through each first vertical opening, of the plurality of first vertical openings intersected by a second pair of second vertical openings, the second pair of second vertical openings adjacent, and on either side of, where access devices will be formed. The first sacrificial material can be selectively etched to remove the first sacrificial material a first lateral distance back from the third vertical openings. A nitride material can be deposited to fill the plurality of second vertical openings and third vertical openings to form a plurality of nitride lattice support structures.

In some example embodiments, selectively removing the first sacrificial material and the second sacrificial material to form a plurality of channel material channels can include selectively etching the second sacrificial material to uncover the array and reopen the plurality of first vertical openings. The first sacrificial material can then be selectively etched to form a plurality of first horizontal openings to define a plurality of channel material channels extending predominantly in the first horizontal direction.

In some example embodiments, forming the access device between the second pair of nitride lattice support structures can include depositing additional second sacrificial material to cover the array and fill a plurality of first vertical openings and a plurality of first horizontal openings. A fourth vertical opening can be formed through the array extending predominantly in the first lateral direction and positioned between a first nitride lattice support structure, of the second pair of nitride lattice support structures, and a second nitride lattice support structure, of the second pair of nitride lattice support structures, to expose second sidewalls adjacent where access devices will be formed. The second sacrificial material can be selectively etched to remove the oxide material between the first nitride lattice support structure and the second nitride lattice support structure of the second pair of nitride lattice support structures to expose a plurality of channel material channel end portions. A plurality of gate metal runners can be formed extending primarily in the first lateral direction and wrapping around the plurality of channel material channel end portions. Additional second sacrificial material can be deposited between the first nitride lattice support structure and the second nitride lattice support structure of the second pair of nitride lattice support structures to fill the fourth vertical opening and to cover the plurality of channel material channel end portions and the plurality of gate metal runners.

In some example embodiments, forming the plurality of storage nodes can include forming a fifth vertical opening, extending predominantly in the first lateral direction, through the array between a first nitride lattice support structure of the first pair of nitride lattice support structures and a second nitride lattice support structure of the first pair of nitride lattice support structures. A portion of the plurality of channel material channels can be selectively removed to form a plurality of first storage node recesses, the first storage node recesses extending predominantly in the first horizontal direction, from the fifth vertical opening to a first horizontal distance from the second pair of nitride lattice support structures. A first conductive material can be deposited to fill the plurality of first storage node recesses and the fifth vertical opening. The first conductive material can be selectively removed from the fifth vertical opening. A portion of the first conductive material can be selectively removed from the plurality of first storage node recesses between the fifth vertical opening and a second horizontal distance from the second pair of nitride lattice support structures. A layer of a second conductive material can be conformally deposited in the fifth vertical opening and the plurality of first storage node recesses to form a capacitor bottom electrode. The exposed second sacrificial material can be selectively recessed to form a plurality of second storage node recesses. A capacitor middle insulating material layer can be conformally deposited on the capacitor bottom electrode, in the fifth vertical opening, the plurality of first storage node recesses, and the plurality of second storage node recesses; and a third conductive material can be deposited to fill the fifth vertical opening, first storage node recess, and second storage node recess to form a double sided capacitor top electrode.

In some example embodiments, the second conductive material can be titanium nitride. In some example embodiments, the first horizontal distance can be between 0 nm and 50 nm. In some example embodiments, a horizontal capacitor of the array has a length of between 0 nm and 150 nm. In some example embodiments, a memory device can include an array of vertically stacked memory cells, the array of vertically stacked memory cells having horizontally oriented access devices and horizontally oriented storage nodes. The array of vertically stacked memory can include horizontally oriented access devices having first source/drain regions and second source/drain regions separated by channels, and having gates opposing the channels and separated therefrom by the gate dielectrics. The array of vertically stacked memory can also include vertically oriented conductive lines coupled to the gates and separated from the channels by the gate dielectrics, and storage nodes formed in the array of vertically stacked memory cells. The array of vertically stacked memory can further include a plurality of nitride lattice support structures supporting the horizontally oriented storage devices.

In some example embodiments, the storage nodes can be double sided capacitors having a bottom electrode, and a top electrode on either side of the bottom electrode and separated from the bottom electrode by a middle insulating material layer. The plurality of nitride lattice support structures can be positioned such that a nitride lattice support structure of the plurality of nitride lattice support structures can be horizontally positioned adjacent to and on either side of a top electrode exit area and either side of the horizontally oriented access device. The nitride lattice support structures can also be positioned on either side of the source/drain region include a plurality of vertical support structure portions extending vertically down through every second open between each column of the plurality of columns of storage nodes in the array of vertically stacked memory cells, and the nitride lattice support structures can be positioned on either side of the access device area include a plurality of vertical support structure portions extending vertically down through every second opening between each column of the plurality of columns of storage nodes in the array of vertically stacked memory cells.

Some example embodiments can also include vertically oriented access lines coupled to the gates and separated from the channel region by the gate dielectric; and horizontally oriented digit lines electrically coupled to the second source/drain regions of the access devices.

In some example embodiments, the orientation of the array of vertically stacked memory device can be changed. In some embodiments the array of vertically stacked memory cells can have a vertically oriented access device.

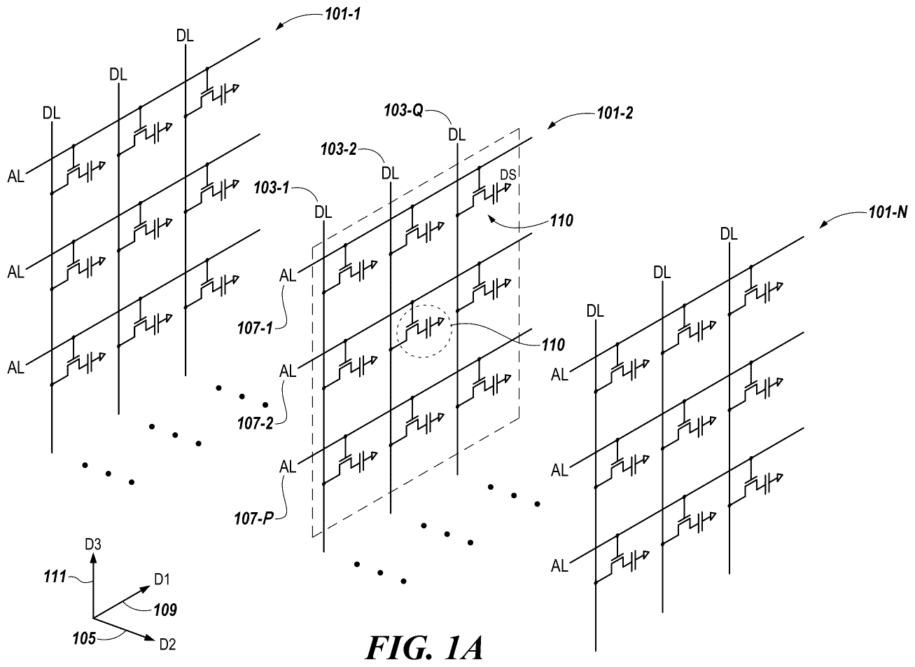

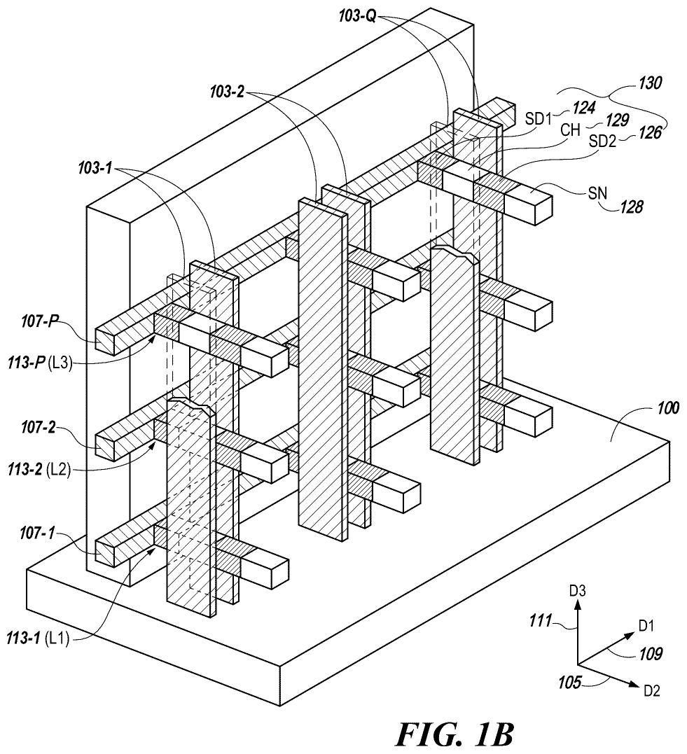

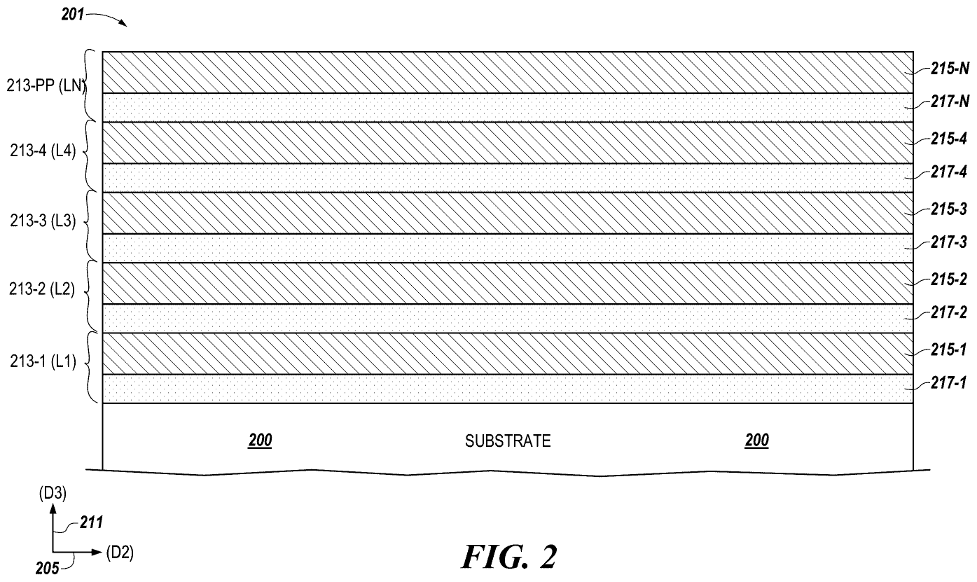

The figures herein follow a numbering convention in which the first digit or digits correspond to the figure number of the drawing and the remaining digits identify an element or component in the drawing. Similar elements or components between different figures may be identified by the use of similar digits. For example, reference numeral 101 may reference element “01” in FIG. 1A, and a similar element may be referenced as 201 in FIG. 2. Multiple analogous elements within one Figure may be referenced with a reference numeral followed by a hyphen and another numeral or a letter. For example, 319-1 may reference element 319-1 in FIG. 3A and 319-2 may reference element 319-2, which may be analogous to element 319-1. Such analogous elements may be generally referenced without the hyphen and extra numeral or letter. For example, elements 319-1 and 319-2 or other analogous elements may be generally referenced as 319.

FIG. 1A is a block diagram of an apparatus in accordance with a number of embodiments of the present disclosure. FIG. 1A illustrates a circuit diagram showing a cell array of a three-dimensional (3D) semiconductor memory device according to embodiments of the present disclosure. FIG. 1A illustrates a cell array having a plurality of sub cell arrays 101-1, 101-2, . . . , 101-N. The sub cell arrays 101-1, 101-2, . . . , 101-N may be arranged along a second direction (D2) 105. Each of the sub cell arrays, (e.g., sub cell array 101-2) may include a plurality of digit lines 103-1, 103-2, . . . , 103-Q (which also may be referred to as bit lines, data lines, or sense lines). Also, each of the sub cell arrays, (e.g., sub cell array 101-2) may include a plurality of access lines 107-1, 107-2, . . . , 107-P (which also may be referred to as word lines). In FIG. 1A, the access lines 107-1, 107-2, . . . , 107-P are illustrated extending in a first direction (D1) 109 (the first direction (D1) 109 is analogous to first direction (D1) 209, 309, 409, 509, 609, 709, 809, 909, 1009, 1109, 1209, 1309, 1409, 1509, 1609, 1709, and 1809 as depicted in figures from FIG. 2 to FIG. 18C, and represents a lateral axis, but may or may not be specifically referenced in the discussion of a given figure.) and the digit lines 103-1, 103-2, . . . , 103-Q are illustrated extending in a third direction (D3) 111. (the third direction (D3) 111 is analogous to third direction (D3) 211, 311, 411, 511, 611, 711, 811, 911, 1011, 1111, 1211, 1311, 1411, 1511, 1611, 1711, and 1811 as depicted in figures from FIG. 2 to FIG. 18C, and represents a vertical axis that is substantially perpendicular to the lateral first direction (D1) 109, but may or may not be specifically referenced in the discussion of a given figure.) According to embodiments, the first direction (D1) 109 and the second direction (D2) 105 may be considered in a horizontal (“X-Y”) plane. (the second direction (D2) 105 is analogous to second direction (D2) 205, 305, 405, 505, 605, 705, 805, 905, 1050, 1105, 1205, 1305, 1405, 1505, 1605, 1705, and 1805 as depicted in figures from FIG. 2 to FIG. 18C, and represents a horizontal axis that is orthogonal to a plane defined by the lateral first direction (D1) and the vertical third direction (D3), but may or may not be specifically referenced in the discussion of a given figure.) The third direction (D3) 111 may be considered in a vertical (“Z”) plane. Hence, according to embodiments described herein, the digit lines 103-1, 103-2, . . . , 103-Q are extending in a vertical direction, (e.g., third direction (D3) 111).

A memory cell, (e.g., memory cell 110) may include an access device, (e.g., an access transistor) and a storage node located at an intersection of each digit line 103-1, 103-2, . . . , 103-Q and each access line 107-1, 107-2, . . . , 107-P. Memory cells may be written to, or read from, using the digit lines 103-1, 103-2, . . . , 103-Q and access lines 107-1, 107-2, . . . , 107-P. The access lines 107-1, 107-2, . . . , 107-P may conductively interconnect memory cells along horizontal columns of each sub cell array 101-, 101-2, . . . , 101-N, and the digit lines 103-1, 103-2, . . . , 103-Q may conductively interconnect memory cells along vertical rows of each sub cell array 101-, 101-2, . . . , 101-N. One memory cell, (e.g., memory cell 110) may be located between one access line, (e.g., digit line 103-2) and one digit line, (e.g., access line 107-2). Each memory cell may be uniquely addressed through a combination of a digit line 103-1, 103-2, . . . , 103-Q and an access line 107-1, 107-2, . . . , 107-P.

The access lines 107-1, 107-2, . . . , 107-P may include conducting patterns (e.g., metal lines) disposed on and spaced apart from a substrate. The access lines 107-1, 107-2, . . . , 107-P may extend in a first direction (D1) 109. The access lines 107-1, 107-2, . . . , 107-P in one sub cell array, (e.g., sub cell array 101-2) may be spaced apart from each other in a vertical direction, (e.g., in a third direction (D3) 111).

The digit lines 103-1, 103-2, . . . , 103-Q may be or include conductive patterns (e.g., metal lines) extending in a vertical direction with respect to the substrate, (e.g., in a third direction (D3) 111). The access lines in one sub cell array, (e.g., sub cell array 101-2) may be spaced apart from each other in the first direction (D1) 109.

A gate of a memory cell, (e.g., memory cell 110) may be connected to an access line, (e.g., access line 107-2) and a first conductive node, (e.g., a first source/drain region) of an access device, (e.g., a transistor), of the memory cell 110 may be connected to a digit line, (e.g., digit line 103-2). Each of the memory cells, (e.g., memory cell 110) may be connected to a storage node, (e.g., a capacitor). A second conductive node, (e.g., a second source/drain region) of the access device, (e.g., a transistor) of the memory cell 110 may be connected to the storage node, (e.g., a capacitor). While first and second source/drain region reference are used herein to denote two separate and distinct source/drain regions, it is not intended that the source/drain region referred to as the “first” and/or “second” source/drain regions have some unique meaning. It is intended only that one of the source/drain regions can be connected to a digit line, (e.g., digit line 103-2) and the other may be connected to a storage node.

In some embodiments the digit lines 103-1, 103-2, . . . , 103-Q may extend in the first direction (D1) 109 and the access lines 107-1, 107-2, . . . , 107-P may extend in the third direction (D3) 111. Such that a memory cell (e.g., 110), as depicted in FIG. 1A, may include an access device (e.g., access transistor) and a storage node located at an intersection of each access line 107-1, 107-2, . . . , 107-P and each digit line 103-1, 103-2, . . . , 103-Q. Memory cells may be written to, or read from, using the access lines 107-1, 107-2, . . . , 107-P and digit lines 103-1, 103-2, . . . , 103-Q. The digit lines 103-1, 103-2, . . . , 103-Q may conductively interconnect memory cells along horizontal columns of each sub cell array 101-, 101-2, . . . , 101-N, and the access lines 107-1, 107-2, . . . , 107-P may conductively interconnect memory cells along vertical rows of each sub cell array 101-1, 101-2, . . . , 101-N. One memory cell, (e.g., memory cell 110) may be located between one access line (e.g., 107-2) and one digit line (e.g., 103-2). Each memory cell may be uniquely addressed through a combination of an access line 107-1, 107-2, . . . , 107-P and a digit line 103-1, 103-2, . . . , 103-Q.

The digit lines 103-1, 103-2, . . . , 103-Q may include conducting patterns (e.g., metal lines) disposed on and spaced apart from a substrate. The digit lines 103-1, 103-2, . . . , 103-Q may extend in a first direction (D1) 109. The digit lines 103-1, 103-2, . . . , 103-Q in one sub cell array (e.g., 101-2) may be spaced apart from each other in a vertical direction (e.g., in a third direction (D3) 111).

The access lines 107-1, 107-2, . . . , 107-P may be or include conductive patterns (e.g., metal lines) extending in a vertical direction with respect to the substrate (e.g., in a third direction (D3) 111). The access lines in one sub cell array (e.g., 101-2) may be spaced apart from each other in the first direction (D1) 109.

A gate of a memory cell (e.g., memory cell 110) may be connected to an access line (e.g., 107-2) and a first conductive node (e.g., first source/drain region) of an access device (e.g., transistor) of the memory cell 110 may be connected to a digit line (e.g., 103-2). Each of the memory cells (e.g., memory cell 110) may be connected to a storage node (e.g., capacitor). A second conductive node (e.g., second source/drain region) of the access device (e.g., transistor) of the memory cell 110 may be connected to the storage node (e.g., capacitor). Storage nodes, such as capacitors, can be formed from ferroelectric and/or dielectric materials such as zirconium oxide (ZrO2), hafnium oxide (HfO2) oxide, lanthanum oxide (La2O3), lead zirconate titanate (PZT, Pb[Zr(x)Ti(1-x)]O3), barium titanate (BaTiO3), aluminum oxide (e.g., Al2O3), a combination of these with or without dopants, or other suitable materials.

FIG. 1B illustrates an alternative embodiment perspective view showing a three-dimensional (3D) semiconductor memory device (e.g., a portion of a sub cell array 01-2 shown in FIG. 1A as a vertically oriented stack of memory cells in an array) according to some embodiments of the present disclosure. As shown in FIG. 1B, a substrate 100 may have formed thereon one of the plurality of sub cell arrays (e.g., 101-2) described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells (e.g., memory cell 110 in FIG. 1A) extending in a vertical direction (e.g., third direction (D3) 111). According to some embodiments the vertically oriented stack of memory cells may be fabricated such that each memory cell (e.g., memory cell 110 in FIG. 1A) can be formed on plurality of vertical levels (e.g., a first level (L1), a second level (L2), and a third level (L3)). The repeating, vertical levels, L1, L2, and L3, may be arranged (e.g., “stacked”) a vertical direction (e.g., third direction (D3) 111 shown in FIG. 1A) and may be separated from the substrate 100 by an insulator material 120. Each of the repeating, vertical levels, L1, L2, and L3 may include a plurality of discrete components (e.g., regions) to the laterally oriented access devices 130 (e.g., transistors) and storage nodes (e.g., capacitors) including, in this embodiment, horizontally oriented digit lines 107-1, 107-2, . . . , 107-P connections and, in this embodiment, vertically oriented access lines 103-1, 103-2, . . . , 103-Q connections. The plurality of discrete components to the laterally oriented access devices 130 (e.g., transistors) may be formed in a plurality of iterations of vertically, repeating layers within each level, and may extend horizontally in the second direction (D2) 105, analogous to second direction (D2) 105 shown in FIG. 1A.

The plurality of discrete components to the laterally oriented access devices 130 (e.g., transistors) may include a first source/drain region 124 and a second source/drain region 126 separated by a channel region 129, extending laterally in the second direction (D2) 105, and formed in a body of the access devices. In some embodiments, the channel region 129 may include materials such as silicon, germanium, silicon-germanium, and/or indium gallium zinc oxide (IGZO). In some embodiments, a multilayer channel material may be deposited as the channel regions. In some examples, the channel material may be deposited to have a width greater than the thickness of the channel material. In some embodiments, the first and the second source/drain regions, 124 and 126, can include an n-type dopant region formed in a p-type doped body to the access device to form an n-type conductivity transistor. In some embodiments, the first and the second source/drain regions, 124 and 126, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 128 (e.g., capacitor) may be connected to one respective end of the access device. As shown in FIG. 1B, the storage node 128 (e.g., capacitor and/or double sided capacitor) may be connected to the second source/drain region 126 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell (e.g., memory cell 110 in FIG. 1A) may similarly extend in the second direction (D2) 105, analogous to second direction (D2) 105 shown in FIG. 1A.

As shown in the embodiment of FIG. 1B a plurality of vertically oriented access lines 103-1, 103-2, . . . , 103-Q extend in the third direction (D3) 111, analogous to the third direction (D3) 111 in FIG. 1A. In this embodiment, the plurality of vertically oriented access lines 103-1, 103-2, . . . , 103-Q are flipped ninety degrees to be oriented vertically relative to the horizontally oriented access lines 107-1, 107-2, . . . , 107-P shown in FIG. 1A. In this embodiment, the plurality of vertically oriented access lines 103-1, 103-2, . . . , 103-Q may be arranged (e.g., “stacked”) along the first direction (D1) 109. The plurality of vertically oriented access lines 103-1, 103-2, . . . , 103-Q may include a first conductive line material. For example, the first conductive line material may include one or more of a doped semiconductor (e.g., doped silicon, doped germanium, etc.) a conductive metal nitride (e.g., titanium nitride, tantalum nitride, etc.) a metal (e.g., tungsten (W), titanium (Ti), tantalum (Ta), ruthenium (Ru), cobalt (Co), molybdenum (Mo), etc.) and/or a metal-semiconductor compound (e.g., tungsten silicide, cobalt silicide, nickel silicide, titanium silicide, etc.) Embodiments, however, are not limited to these examples.

Among each of the vertical levels, (L1) 113-1, (L2) 113-2, and (L3) 113-P, the horizontally oriented memory cells (e.g., memory cell 110 in FIG. 1A) may be spaced apart from one another horizontally in the first direction (D1) 109. However, the plurality of discrete components to the laterally oriented access devices 130 (e.g., first source/drain region 124 and second source/drain region 126 separated by a channel region 129), extending laterally in the second direction (D2) 105, and the plurality of horizontally oriented digit lines 107-1, 107-2, . . . , 107-P, extending laterally in the first direction (D1) 109, may be formed within different vertical layers within each level. For example, the plurality of horizontally oriented digit lines 107-1, 107-2, . . . , 107-P, extending in the first direction (D1) 109, may be disposed on, and in electrical contact with, surfaces of first source/drain regions 124 and orthogonal to laterally oriented access devices 130 (e.g., transistors) extending laterally in the second direction (D2) 105. In some embodiments, the plurality of horizontally oriented digit lines 107-1, 107-2, . . . , 107-P, extending in the first direction (D1) 109 are formed in a higher vertical layer, farther from the substrate 100, within a level (e.g., within level (L1)) than a layer in which the discrete components (e.g., first source/drain region 124 and second source/drain region 126 separated by a channel region 129) of the laterally oriented access device are formed. In some embodiments, the plurality of horizontally oriented digit lines 107-1, 107-2, . . . , 107-P, extending in the first direction (D1) 109, may be connected to the top surfaces of the first source/drain regions 124 directly and/or through additional contacts including metal silicides.

As shown in the example embodiment of FIG. 1B, the access lines, 103-1, 103-2, . . . , 103-Q, extend in a vertical direction with respect to the substrate 100 (e.g., in a third direction (D3) 111). Further, as shown in FIG. 1B, the access lines, 103-1, 103-2, . . . , 103-Q, in one sub cell array (e.g., sub cell array 101-2 in FIG. 1A) may be spaced apart from each other in the first direction (D1) 109. The access lines, 103-1, 103-2, . . . , 103-Q, may be provided, extending vertically relative to the substrate 100 in the third direction (D3) 111 between a pair of the laterally oriented access devices 130 (e.g., transistors) extending laterally in the second direction (D2) 105, but adjacent to each other on a level (e.g., first level (L1)) in the first direction (D1) 109. Each of the access lines, 103-1, 103-2, . . . , 103-Q, may vertically extend, in the third direction (D3) 111, on sidewalls of respective ones of the plurality of laterally oriented access devices 130 (e.g., transistors) that are vertically stacked.

For example, a first one of the vertically extending access lines (e.g., 103-1) may be adjacent a sidewall of a channel region 129 to a first one of the laterally oriented access devices 130 (e.g., transistors) in the first level (L1) 113-1, a sidewall of a channel region 129 of a first one of the laterally oriented access devices 130 (e.g., transistors) in the second level (L2) 113-2, and a sidewall of a channel region 129 a first one of the laterally oriented access devices 130 (e.g., transistors) in the third level (L3) 113-P, etc. Similarly, a second one of the vertically extending access lines (e.g., 103-2) may be adjacent a sidewall to a channel region 129 of a second one of the laterally oriented access devices 130 (e.g., transistors) in the first level (L1) 113-1, spaced apart from the first one of laterally oriented access devices 130 (e.g., transistors) in the first level (L1) 113-1 in the first direction (D1) 109. And the second one of the vertically extending access lines (e.g., 103-2) may be adjacent a sidewall of a channel region 129 of a second one of the laterally oriented access devices 130 (e.g., transistors) in the second level (L2) 113-2, and a sidewall of a channel region 129 of a second one of the laterally oriented access devices 130 (e.g., transistors) in the third level (L3) 113-P, etc. Embodiments are not limited to a particular number of levels. In some embodiments, the vertically extending access lines (e.g., 103-2) may be deposited to have a width greater than the horizontal length of the channels, overlapping both the first and the second source/drain regions horizontally. In another embodiment, the vertically extending access lines (e.g., 103-2) may be deposited to have a width less than the horizontal length of the channels, underlapping both the first and the second source/drain regions horizontally.

The vertically extending access lines, 103-1, 103-2, . . . , 103-Q, may include a first conductive material, such as, for example, one of a doped semiconductor material, a conductive metal nitride, metal, and/or a metal-semiconductor compound. The access lines, 103-1, 103-2, . . . , 103-Q, may correspond to word lines (WL) described in connection with FIG. 1A.

In the example embodiment of FIG. 1B, a conductive body contact (not shown) may be formed extending in the first direction (D1) 109 along an end surface of the laterally oriented access devices 130 (e.g., transistors) in each level (L1) 113-1, (L2) 113-2, and (L3) 113-P above the substrate 100. The body contact may be connected to a body (e.g., body region) of the laterally oriented access devices 130 (e.g., transistors) in each memory cell (e.g., memory cell 110 in FIG. 1A). The body contact may include a first conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

A unit cell, (e.g., memory cell 110 in FIG. 1A) of the vertically stacked array of memory cells, (e.g., within a sub cell array 101-2 in FIG. 1A) according to some embodiments of the present disclosure. The first and the second source/drain regions, 124 and 126, may be impurity doped regions to the horizontally oriented, access devices 130, (e.g., transistors). The first and the second source/drain regions, 124 and 126, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In₂O₃), or indium tin oxide (In₂₋ₓSnₓO₃), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants (e.g., phosphorous (P), boron (B), etc.). Non-degenerate semiconductors, by contrast, contain moderate levels of doping, where the dopant atoms are well separated from each other in the semiconductor host lattice with negligible interaction.

The first source/drain region 124 and the second source/drain region 126 may be separated by a channel 129, (e.g., a channel region) of the horizontally oriented, access devices 130, (e.g., transistors) The channel 129 may be a low-doped (p-) polysilicon material. In some embodiments, the channel 129 may be a low-doped (p-) poly-germanium (Ge) material. In some embodiments, the channel 129 may be a low doped (p-) poly-silicon-germanium (poly-SiGe) material However, in some embodiments the channel 129 may be comprised of a semiconductor oxide (also referred to herein as an “oxide semiconductor” or “oxide semiconductor material”). The semiconductor oxide may comprise any suitable composition; and in some embodiments may include one or more of indium, zinc, tin and gallium. Examples of oxide semiconductor materials and/or compositions, as used herein, including one or more of indium, zinc, tin and gallium may include such materials as ZnOₓ, InOₓ, SnO₂, ZnₓO_{y}N, MgₓZn_{y}O_{z}, InₓZn_{y}O_{z}, InₓZn_{y}O_{z}, InₓGa_{y}Zn_{z}Oₐ, InₓGa_{y}Si_{z}Oₐ, ZrₓIn_{y}Zn_{z}Oₐ, HfₓIn_{y}Zn_{z}Oₐ, SnₓIn_{y}Zn_{z}Oₐ, AlₓSn_{y}In_{z}ZnₐO_{b}, SiₓIn_{y}Zn_{z}Oₐ, ZnₓSn_{y}O_{z}, AlₓZn_{y}Sn_{z}Oₐ, GaₓZn_{y}Sn_{z}Oₐ, and ZrₓZn_{y}Sn_{z}Oₐ.

In additional embodiments, the channel 129 may be comprised of a two-dimensional (2D) material. The 2D material may comprise any suitable composition; and in some embodiments may include one or more of a transition metal dichalcogenide, including molybdenum disulfide (MoS₂), molybdenum diselenide (MoSe₂), molybdenum ditelluride (MoTe₂), tungsten sulfide (WS₂), and tungsten selenide (WSe₂). Embodiments, however, are not limited to these examples.

In some embodiments, the channel 129 may comprise a composite material such as an indium gallium zinc oxide (In₂Ga₂ZnO₇) material (also referred to herein as “IGZO”). In some embodiments, the composite IGZO material can be a multi-layer I₂G₂ZnO₇ channel that can be indium (In) rich in a first layer, closest to a surface of the channel opposing a gate dielectric, relative to the multiple layers. In some embodiments, the composite IGZO material can be a multi-layer I₂G₂ZnO₇ channel that can be gallium (Ga) rich in an outer layer, farthest from a surface of the channel opposing a gate dielectric, relative to the multiple layers. And, in some embodiments, the composite IGZO material can be a multi-layer I₂G₂ZnO₇ channel that can be zinc (Zn) rich in an outer layer, farthest from a surface of the channel opposing a gate dielectric, relative to the multiple layers, etc. Embodiments, however, are not limited to these examples. In some embodiments, the channel 129 may be a gradient channel region having a decreasing indium (In) concentration in the gradient channel region in a direction away from a gate dielectric.

In the example embodiment of FIG. 1B, an access line, (e.g., access line 103-1) may be analogous to the access lines 107-1, 107-2, . . . , 107-P in FIG. 1A. A digit line, (e.g., digit line 107-1), analogous to the digit lines 103-1, 103-2, . . . , 103-Q shown in FIG. 1A, may be formed in electrical contact with the first source/drain region 124. As shown in the example embodiment of FIG. 1B, an access line, (e.g., access line 103-1) may be vertically extending in the third direction (D3) 111 adjacent sidewall of the channel region 129 of the horizontally oriented, access devices 130, (e.g., transistors) horizontally conducting between the first and the second source/drain regions 124 and 126 along the second direction (D2) 105. A gate dielectric material may be interposed between the access line 103-1 (a portion thereof forming a gate to the horizontally oriented, access devices 130, (e.g., transistors) and the channel region 129. The gate dielectric material 104 may include, for example, a high-k dielectric material, a silicon oxide material (e.g., silicon dioxide (SiO₂), a silicon nitride material, a silicon oxynitride material, etc., or a combination thereof. Embodiments are not so limited. For example, in high-k dielectric material examples the gate dielectric material 104 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

Although FIG. 1A and FIG. 1B are depicted reciprocally horizontally oriented access/digit lines and vertically oriented access/digit lines, other configurations are possible. For example, in some embodiments a unit cell (e.g., unit cell 110) may have horizontally, orthogonally oriented access/digit lines and vertically oriented access devices 130.

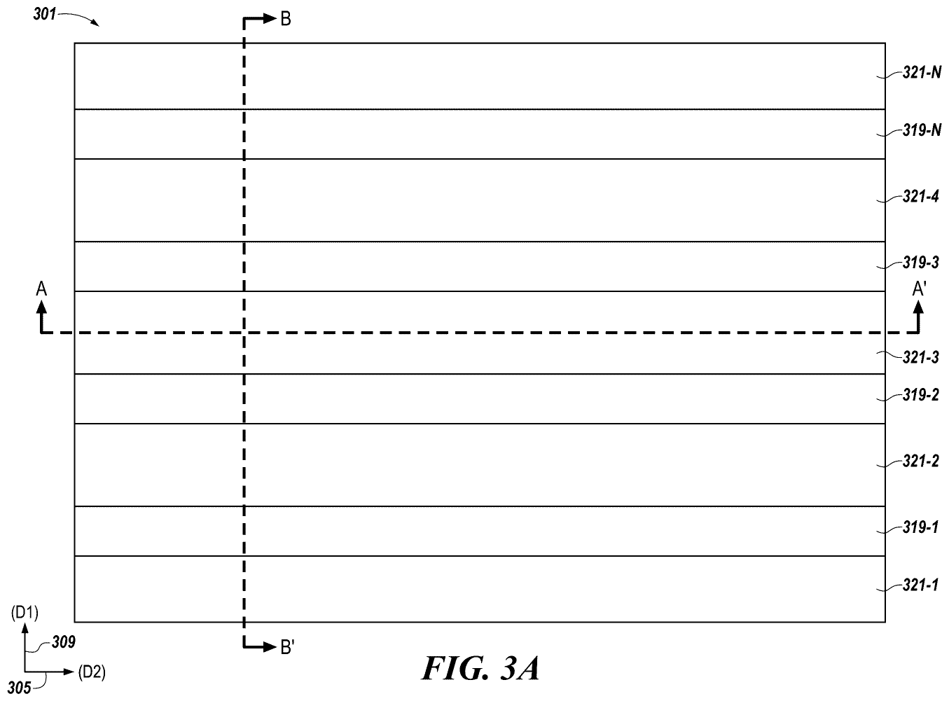

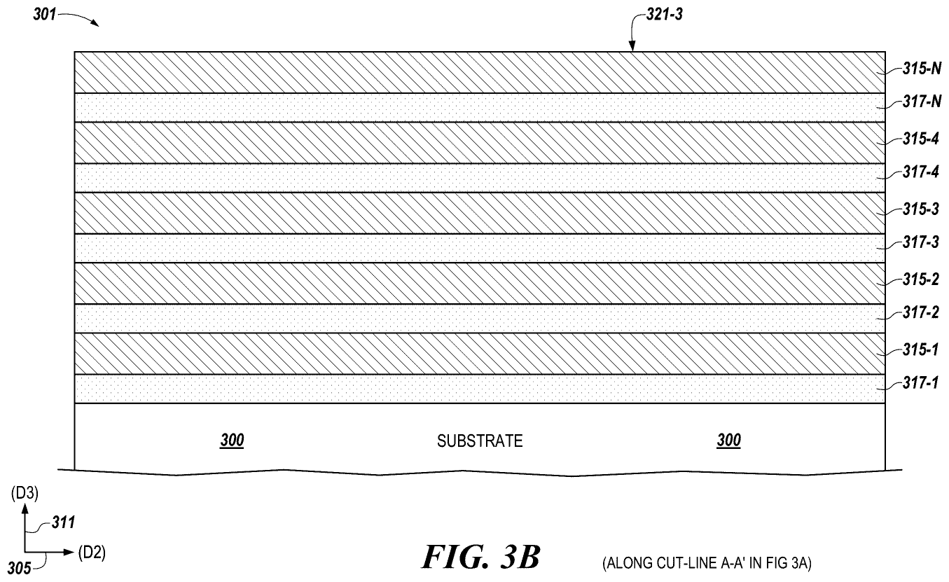

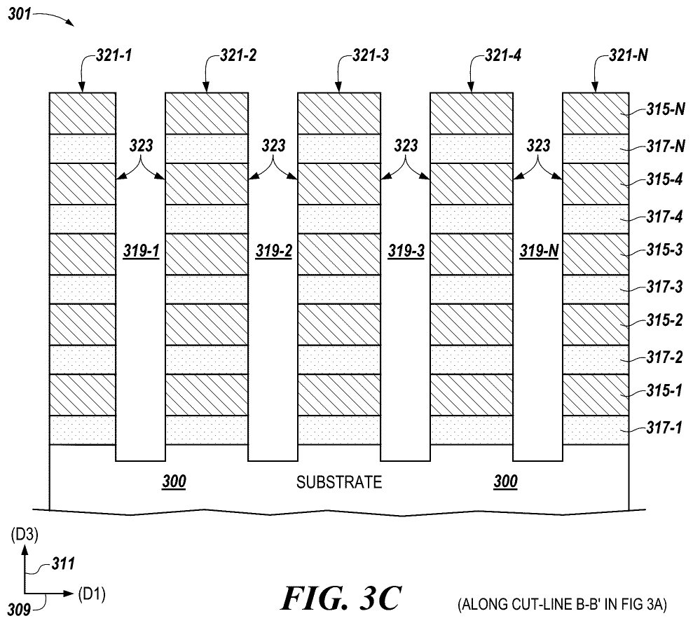

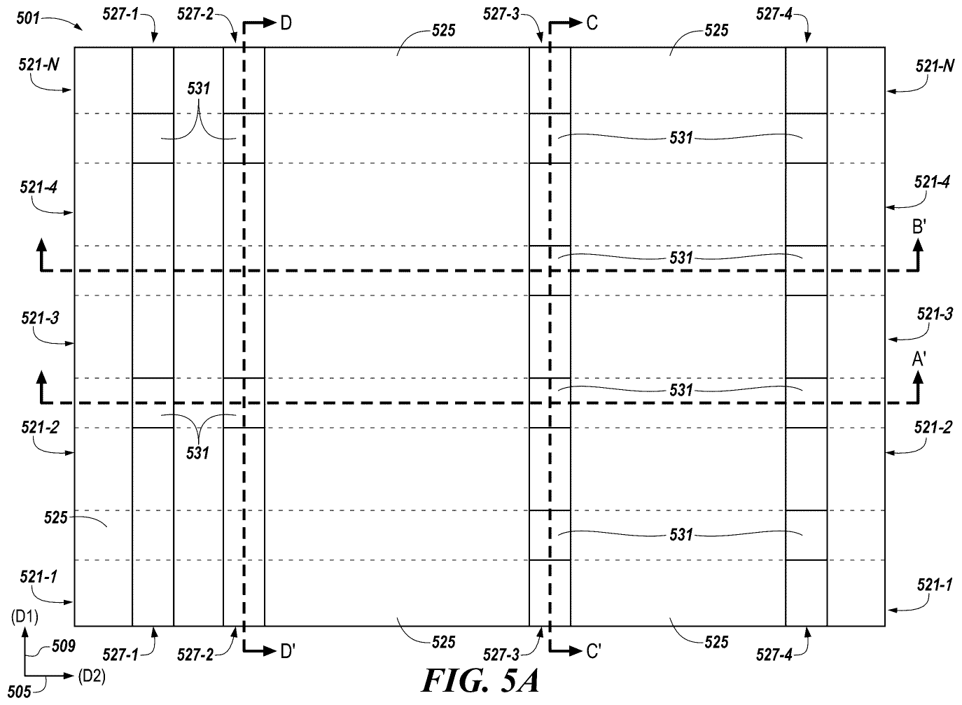

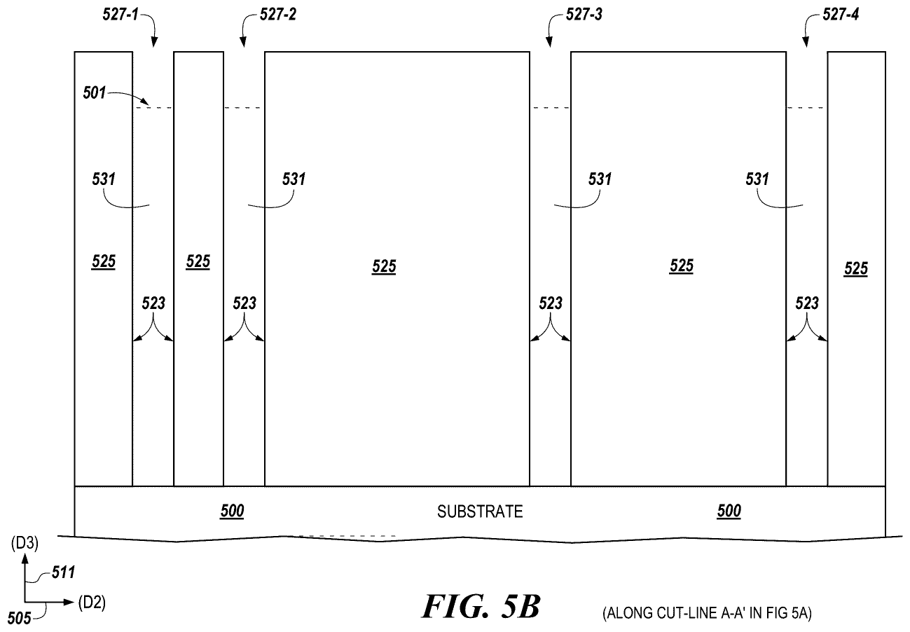

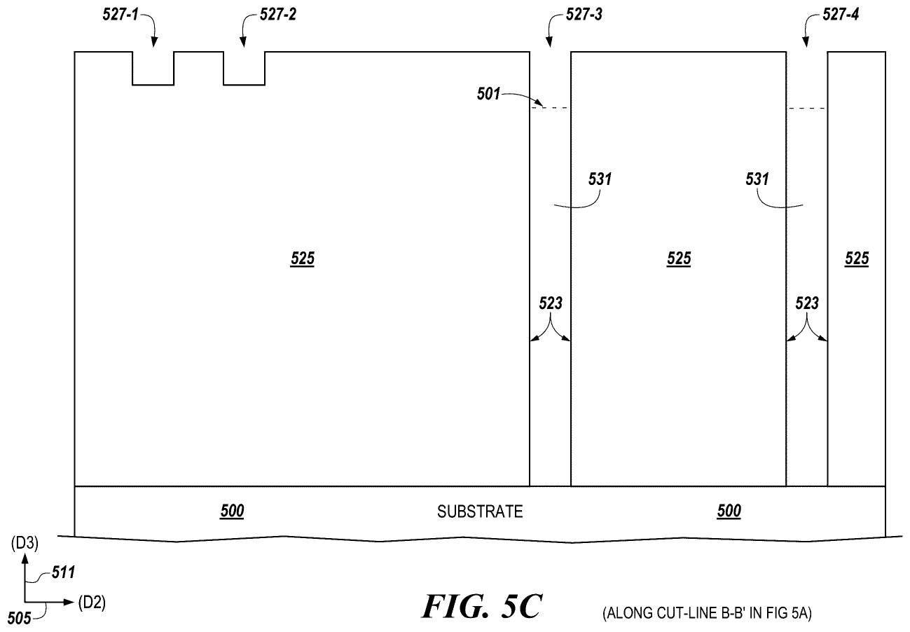

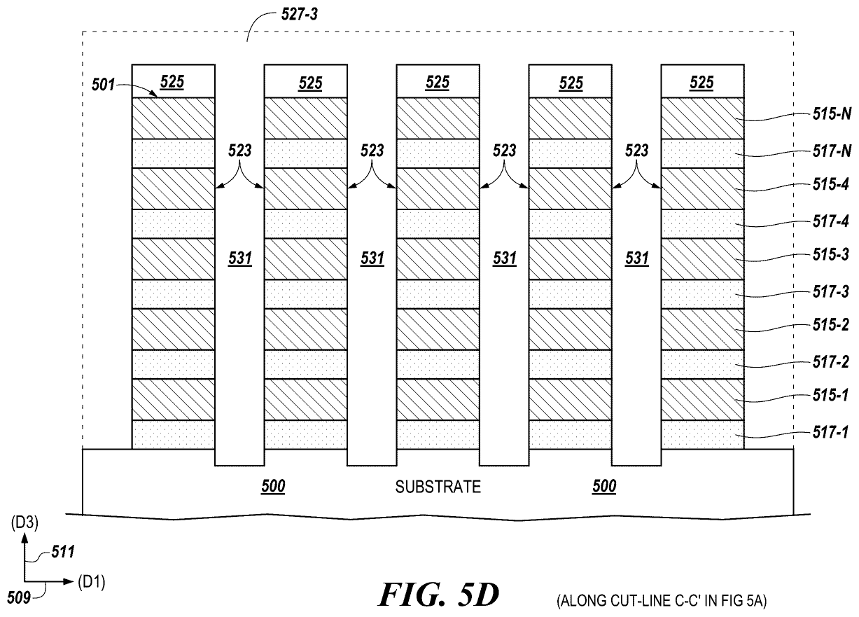

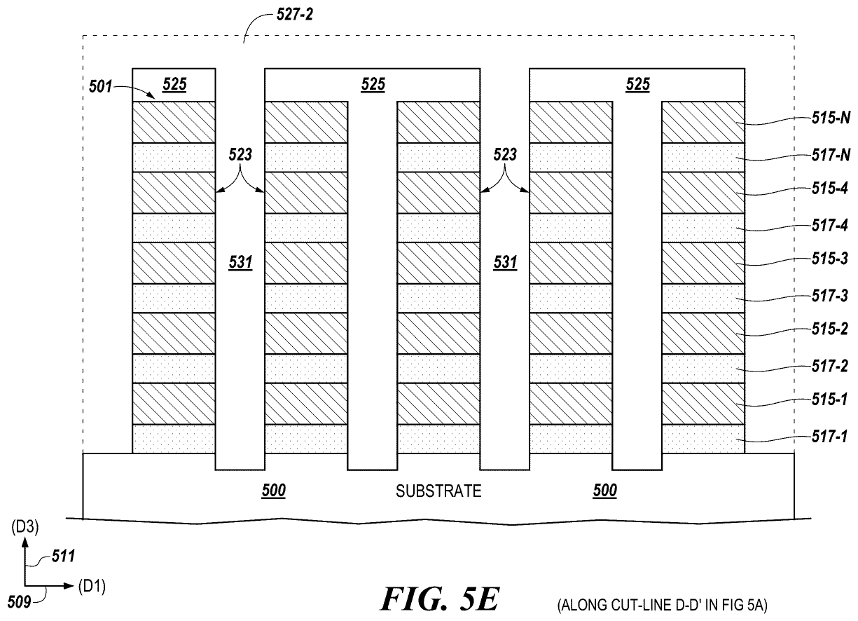

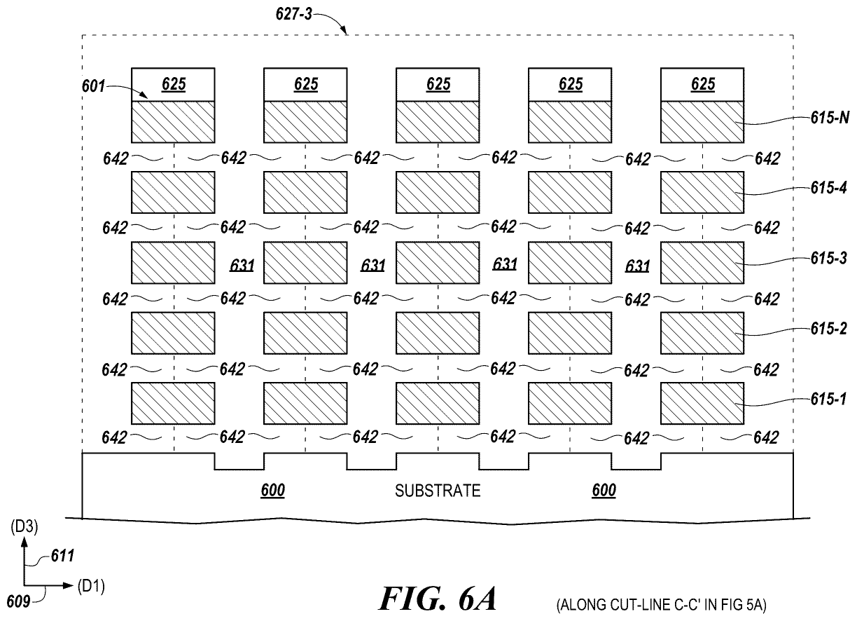

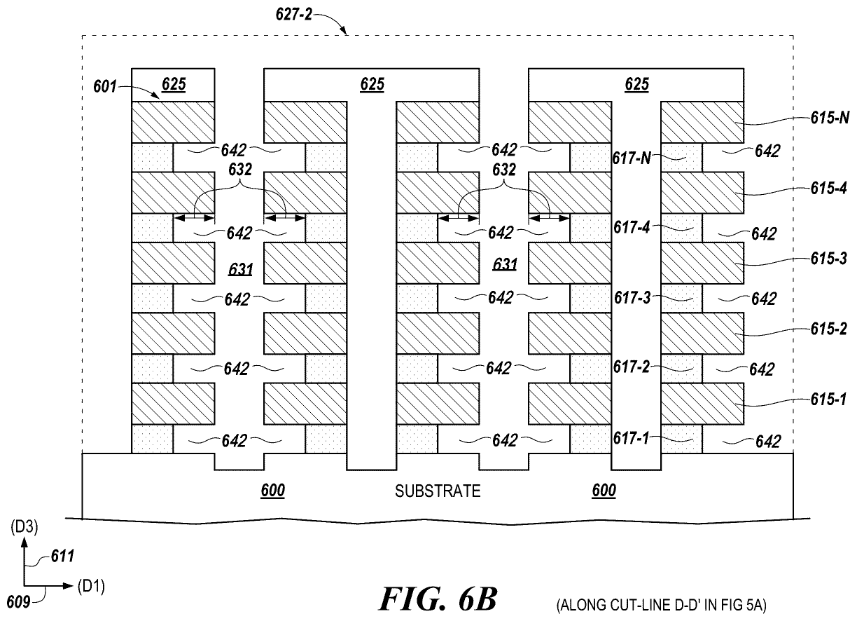

FIG. 2 through FIG. 18C herein following a numbering convention in which the numerical digits correspond to a stage of a manufacturing process and the letters, or lack of a letter, correspond to various perspectives at said stage of the manufacturing process. For example, FIG. 5A, FIG. 5B, FIG. 5C, FIG. 5D, and FIG. 5E represent a variety of views of a single stage of a manufacturing process while FIG. 6A, and FIG. 6B both represent views of another single stage of a manufacturing process. While similar numerals represent the same stage of manufacturing, similar letters do not necessarily represent the same perspectives. For example, FIG. 5A show a top down view of a stage of the manufacturing process while FIG. 6A displays a cross section which would be perpendicular to the view shown in FIG. 5A. As another example, FIG. 2 and FIG. 3B show a similar cross section of two different stages of the manufacturing process.

FIG. 2 illustrates an example method, at one stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 2 shows a cross section along the horizontal second direction (D2) 205 and the vertical third direction (D3) 211. In the example embodiment shown in the example of FIG. 2, the method comprises depositing alternating layers 213 of a channel material, 215-1, 215-2, . . . , 215-N (also referred to herein independently and/or collectively as “215”), such as epitaxially grown silicon (Si), and a sacrificial material, 217-1, 217-2, . . . , 217-N (also referred to herein independently and/or collectively as “217”), such as epitaxially grown silicon germanium (SiₓGe₁₋ₓ), in repeating iterations to form a vertical stack 201 on a working surface of a semiconductor substrate 200. (Semiconductor substrate 200 is analogous to semiconductor substrate 300, 400, 500, 600, 700, 800, 900, 1000, 1100, 1200, 1300, 1400, 1500, 1600, 1700, and 1800 as depicted in figures from FIG. 3A to FIG. 18C, but may or may not be specifically referenced in the discussion of a given figure.) In one embodiment, the channel material 215 can be deposited to have a thickness, (e.g., vertical height in the third direction (D3)) in a range of five (5) nanometers (nm) to sixty (60) nm. In one embodiment, the sacrificial material 217 can be deposited to have a thickness, (e.g., vertical height) in a range of five (5) nm to one hundred (100) nm. Embodiments, however, are not limited to these examples.

In one example, the sacrificial material, 217-1, 217-2, . . . , 217-N, can comprise a first sacrificial material such as polycrystalline silicon (Si), silicon nitride (Si₃N₄), silicon germanium (SiGe) or even an oxide-based semiconductor composition. While the discussion herein will refer to a first sacrificial material example, embodiments are not limited to this example. It is intended that the sacrificial material may be selectively etched relative to the alternating layer of channel material, 215-1, 215-2, . . . , 215-N.

As shown in FIG. 2, a vertical direction is illustrated as a third direction (D3) 211, (e.g., z-direction in an x-y-z coordinate system) analogous to the third direction (D3) 111 in FIG. 1A, among first, second and third directions, shown in FIG. 1. In the example of FIG. 2, five tiers, numbered 1, 2, 3, 4, and 5, of the repeating iterations of the vertical stack 201 are shown. Embodiments, however, are not limited to this example and more or fewer repeating iterations may be included. A photolithographic hard mask (HM) layer may be deposited as a top layer on the repeating iterations of the vertical stack 201.

The repeating iterations of alternating channel material, 215-1, 215-2, . . . , 215-N, layers and first sacrificial material, 217-1, 217-2, . . . , 217-N, layers may be deposited according to a semiconductor fabrication process such as chemical vapor deposition (CVD) or epitaxial growth in a semiconductor fabrication apparatus. Embodiments, however, are not limited to this example and other suitable semiconductor fabrication techniques may be used to deposit the alternating layers of a channel material, 215-1, 215-2, . . . , 215-N, and a first sacrificial material, 217-1, 217-2, . . . , 217-N, in repeating iterations to form a vertical stack 201, as shown in FIG. 2.

FIG. 3A illustrates an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 3A illustrates a top down view of a semiconductor structure, at a particular point in time, in a semiconductor fabrication process, according to one or more embodiments. In the example embodiment shown in the example of FIG. 3A, the method comprises patterning the vertical stack 301 by using an etchant process to form a plurality of first vertical openings 319, having a first lateral direction (D1) 309 and a first horizontal direction (D2) 305, through the vertical stack to the substrate (e.g., substrate 300 shown in FIG. 3C). In one example, as shown in FIG. 3A, the plurality of first vertical openings 319 are extending predominantly in the first horizontal direction (D2) 305 and may form a plurality of elongated vertical columns 321 with sidewalls 323 in the vertical stack. The plurality of first vertical openings 319 may be formed using dry etching techniques. In some examples, the method comprises using a photolithographic process to pattern and to expose particular regions of the vertical stack for forming a plurality of spaced, first vertical openings 319 through the vertical stack adjacent areas where storage nodes will be formed, defining elongated vertical columns 321 of the alternating layers. In some embodiments, a directional anisotropic etch can be used to form the plurality of first vertical openings 319. In some examples, the anisotropic each can be used to etch the resist material, such as an oxide material, from the stack to form the first vertical openings 319 in the stack.

FIG. 3B is a cross sectional view, taken along cut-line A-A′ in FIG. 3A, showing another view of the semiconductor structure at a particular time in the semiconductor fabrication process. FIG. 3B shows a cross section through an elongated vertical column 321-3. FIG. 3B illustrates the repeating iterations of alternating layers of a channel material, 315-1, 315-2, . . . , 315-N, and a first sacrificial material, 317-1, 317-2, . . . , 317-N of the vertical stack 301 on a semiconductor substrate 300.

FIG. 3C is a cross sectional view, taken along cut-line B-B′ in FIG. 3A, showing another view of the semiconductor structure at a particular time in the semiconductor fabrication process. FIG. 3C illustrates the first vertical openings 319 through the repeating iterations of alternating layers of a channel material, 315-1, 315-2, . . . , 315-N, and a first sacrificial material, 317-1, 317-2, . . . , 317-N in the vertical stack 301, creating elongated vertical, pillar columns 321-1, 321-2, . . . , 321-N and exposing first sidewalls 323 of the vertical columns 321. Chemical mechanical planarization (CMP) or other suitable semiconductor fabrication technique may be used to planarize a top surface of the vertical semiconductor stack 301. Similar semiconductor process techniques may be used at other points of the semiconductor fabrication process described herein.

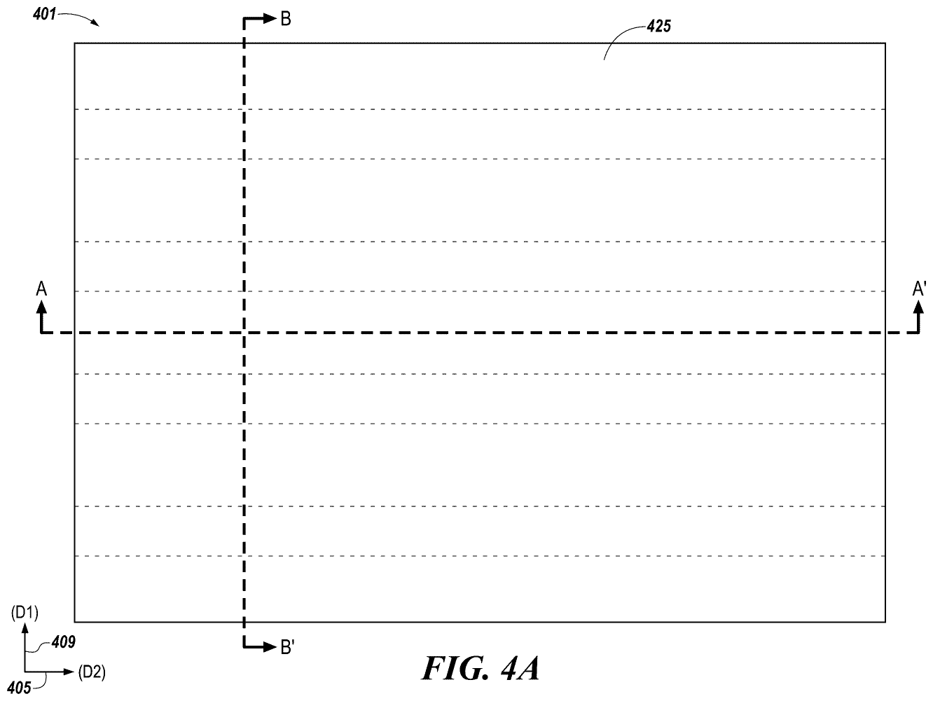

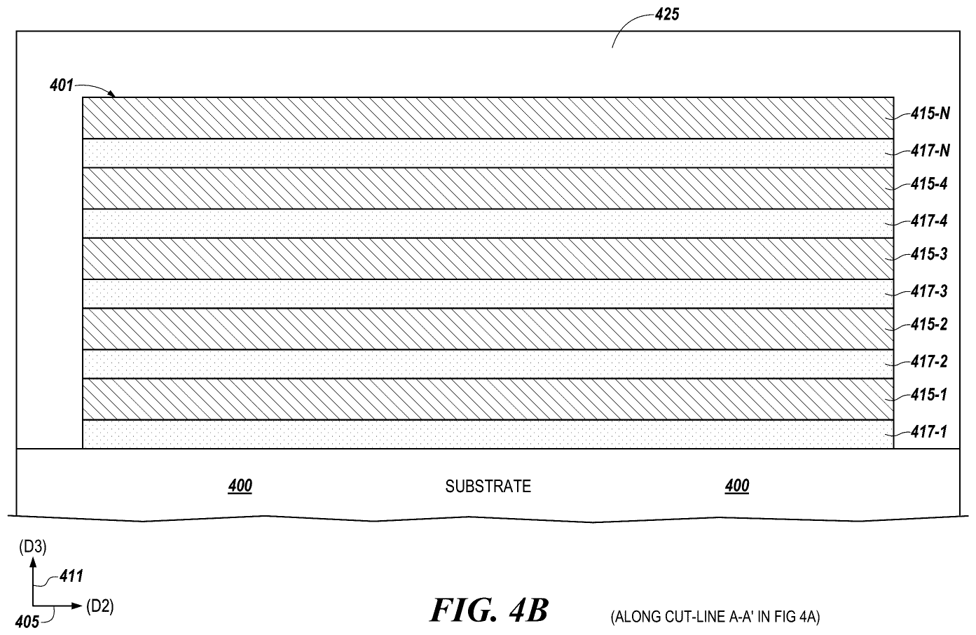

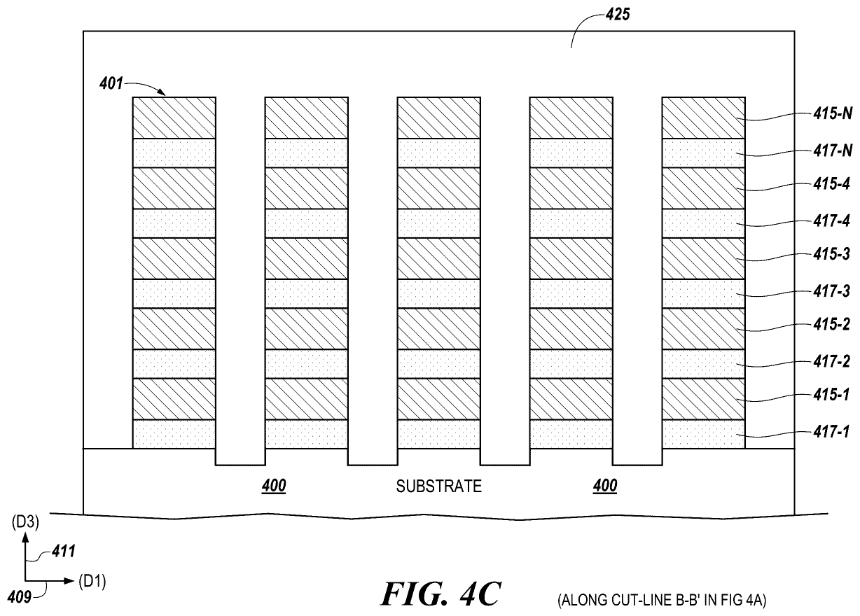

FIG. 4A illustrates an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 4A illustrates a top down view of a semiconductor structure at a particular point in time in a semiconductor fabrication process, according to one or more embodiments. In the example embodiment of FIG. 4A, the method comprises depositing a second sacrificial material 425, such as a first silicon oxide material (e.g., SiO₂) or other suitable dielectric material, to fill the first vertical openings, (e.g., vertical opening 319) and to cover the vertical stack 401. The second sacrificial material 425 can be a first silicon oxide material or other suitable dielectric material, such as, for example, one of a silicon oxide material, a zirconium material, an aluminum oxide material, a zirconium oxide material, etc. Embodiments, however, are not limited to these examples.

FIG. 4B is a cross sectional view, taken along cut-line A-A′ in FIG. 4A, showing another view of the semiconductor structure at a particular time in the semiconductor fabrication process. FIG. 4B illustrates the first oxide material (e.g., SiO₂) layer 425 disposed on the vertical stack 401 of repeating iterations of alternating layers of a channel material, 415-1, 415-2, . . . , 415-N, and a first sacrificial material, 417-1, 417-2, . . . , 417-N, on the semiconductor substrate 400.

FIG. 4C is a cross sectional view, taken along cut-line B-B′ in FIG. 4A, showing another view of the semiconductor structure at a particular time in the semiconductor fabrication process. FIG. 4C illustrates the first oxide material filling the first vertical openings, (e.g., 319 in FIG. 3C), and covering and enclosing the first vertical stack 401 of repeating iterations of alternating layers of a channel material, 415-1, 415-2, . . . , 415-N, and a first sacrificial material, 417-1, 417-2, . . . , 417-N, on the semiconductor substrate 400. The first oxide material 425 may be deposited in the first vertical openings (e.g., vertical openings 319 in FIG. 3C) and planarized to a top surface of the vertical stack 401, (e.g., planarized to a top surface of channel material 315-N) using a process such as chemical mechanical planarization (CMP) or other suitable technique. Additional oxide material 425 may then be deposited to cover and enclose the vertical stack 401 and planarized through a process such as CMP or other suitable technique.

FIG. 5A illustrates an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 5A illustrates a top down view of a semiconductor structure at a particular point in time in a semiconductor fabrication process, according to one or more embodiments. In the example embodiment of FIG. 5A, the method comprises patterning the second sacrificial material, (e.g., the first oxide material 525) by using an etchant process to form a plurality of second vertical openings 527, having a first lateral direction (D1) 509 analogous the first lateral direction (D1) 309 of FIG. 3A and a first horizontal direction (D2) 505 analogous the first horizontal direction (D2) 305 of FIG. 3A, through a portion of the first oxide material 525. In one example, as shown in FIG. 5A, the plurality of second vertical openings 527 extend predominantly in the first lateral direction (D1) 509, substantially perpendicular to, and extending across the filled first vertical openings separating the elongated vertical columns 521 of the vertical stack 501. In some embodiments a plurality of third vertical openings 531 extend between a number of the elongated vertical columns 521.

FIG. 5B is a cross sectional view, taken along a first vertical opening, such as first vertical opening 319-2 in FIG. 3C, throdesignated by cut-line A-A′ in FIG. 5A, showing another view of the semiconductor structure at a particular time in the semiconductor fabrication process. In the example embodiment of FIG. 5B, the method comprises forming a plurality of third vertical openings 531, having a first lateral direction (D1) and a first horizontal direction (D2), through the second vertical openings 527 and the first oxide material 525 filling the first vertical openings, (e.g., vertical opening 319) to the substrate 500. In one example, as shown in FIG. 5B, the plurality of third vertical openings 531 extend predominantly in the first vertical direction (D3) 511 from each second vertical opening and exposing the adjacent portions of the sidewall 523 of each elongated vertical column 521 of the vertical stack 501.

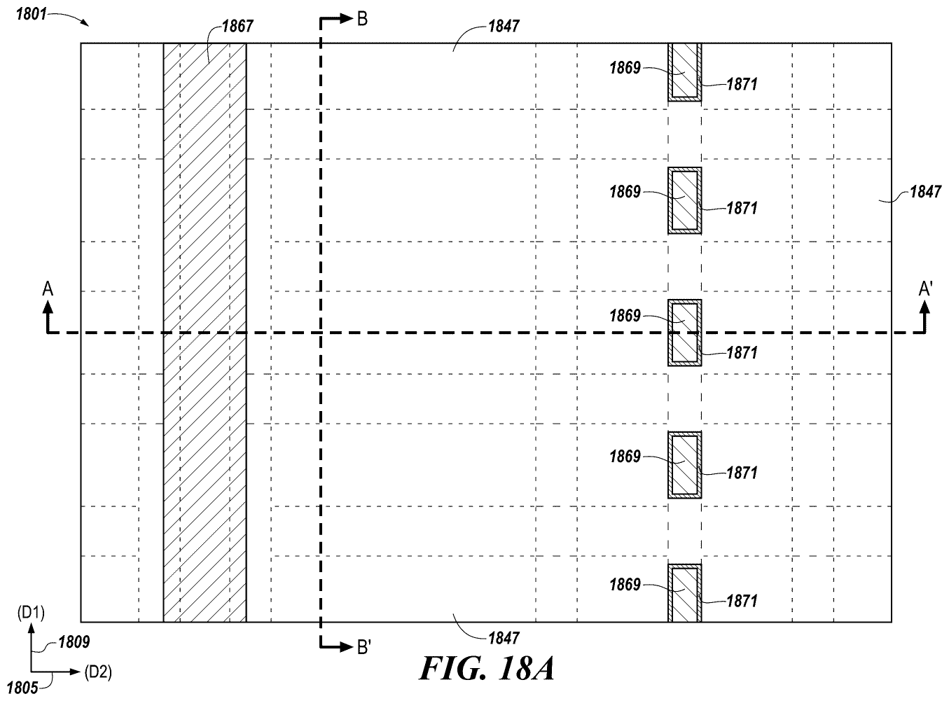

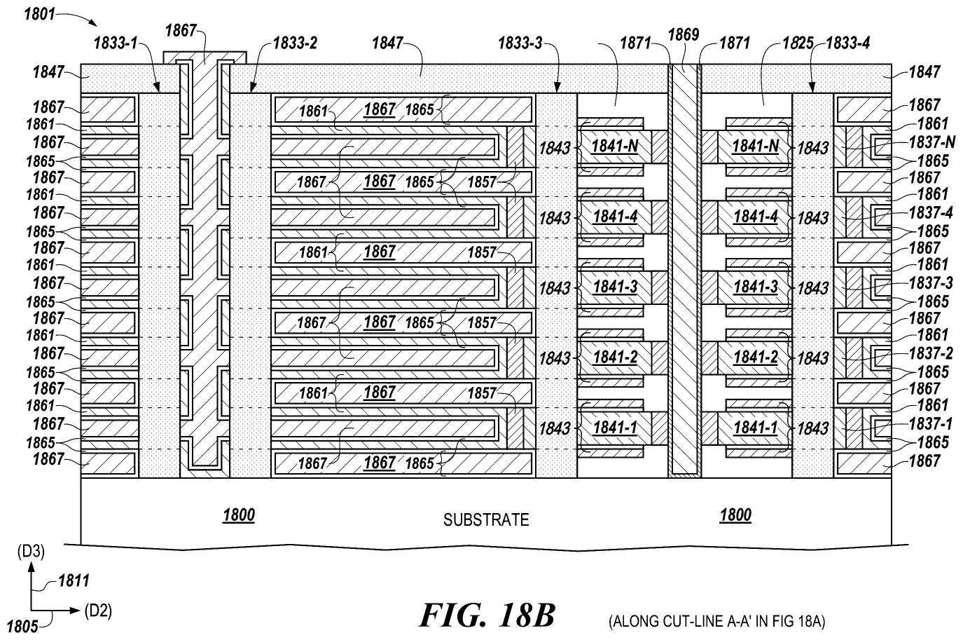

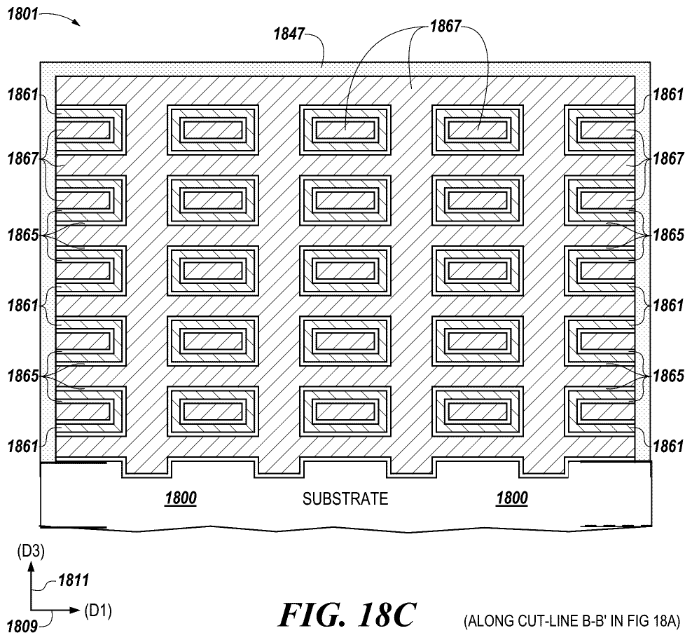

FIG. 5C is a cross sectional view, taken along cut-line B-B′ in FIG. 5A, showing another view of the semiconductor structure at a particular time in the semiconductor fabrication process. FIG. 5C illustrates a cross section parallel to the cross section of FIG. 5B along the next first vertical opening 319-3. In one example, as shown in FIG. 5C, illustrates that the plurality of third vertical openings 531 extending from a first pair of second vertical openings 527-1, 517-2, of the plurality of second vertical openings 527, extend through the second sacrificial material 525 of every other first vertical opening 319-1, 319-3, crossed by the second vertical opening 527 and partially exposing the first sidewalls 523 of the vertical stack 501. In the example embodiment, the first pair of second vertical openings 527-1, 527-2 can be horizontally positioned in the vertical stack 501 such that the first pair of second vertical openings 527-1, 527-2 are adjacent to opposing sides of where a capacitor top electrode, (e.g., capacitor top electrode 1867) as shown in FIG. 18B, exit will be formed. In the example shown in FIG. 5C, the plurality of third vertical openings 531 extending from a second pair of second vertical openings 527-3, 527-4, of the plurality of second vertical openings 527, extend through every first vertical opening 319-1, 319-2, 319-3, . . . , 319-N, crossed by the second vertical opening 527. In the example embodiment, the second pair of second vertical openings 527-3, 527-4 can be horizontally positioned in the vertical stack 501 such that the second pair of second vertical openings 527-3, 527-4 are adjacent to opposing sides of where an access device will be formed, (e.g., gate metal runners 1843 and digit side contacts 1869 as shown in FIG. 18B).

FIG. 5D is a cross sectional view, taken along cut-line C-C′ in FIG. 5A, showing another view of the semiconductor structure at a particular time in the semiconductor fabrication process. The cross sectional view along the second vertical opening 527-3 of the second pair of second vertical openings 527-3, 527-4, as shown in FIG. 5D, illustrates the third vertical openings 531 extending through each filled first vertical opening (e.g., first vertical opening 319 as shown in FIG. 3C) crossed by second vertical opening 527-3, and partially exposing the first sidewalls 523 of the repeating iterations of alternating layers of the channel material 515, and the first sacrificial material 417 of the vertical stack 501. FIG. 5D also illustrates the second vertical openings 527-3 extending completely around the vertical stack 501 to form a trench in the first oxide material 525 along the surface of the vertical stack 501.

FIG. 5E is a cross sectional view, taken along cut-line D-D′ in FIG. 5A, showing another view of the semiconductor structure at a particular time in the semiconductor fabrication process. The cross sectional view along the second vertical opening 527-2 of the first pair of second vertical openings 527-1, 527-2, as shown in FIG. 5E, illustrates the third vertical openings 531 extending through alternating occurrences of the filled first vertical openings (e.g., first vertical openings 319 as shown in FIG. 3C) crossed by second vertical opening 527-2 and partially exposing the first sidewalls of the repeating iterations of alternating layers of the channel material 515, and the first sacrificial material 417 of the vertical stack 501. Although, only a first pair and a second pair of second vertical openings are shown in FIG. 5, embodiments are not so limited. For instance, one or more additional second vertical opening may be formed between the first pair of second vertical openings 527-1, 527-2 and the second pair of second vertical openings 527-3, 527-4. FIG. 5E also illustrates the second vertical opening 527-2 extending completely around the vertical stack 501 to form a trench in the first oxide material 525 along the surface of the vertical stack 501.

FIG. 6A is a cross sectional view, taken along cut-line C-C′ in FIG. 5A, showing an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. In the example embodiment shown in the example of FIG. 6A the method comprises selectively etching the first sacrificial material (e.g., first sacrificial material 517 as shown in FIG. 5D) a first lateral distance (e.g., first lateral distance 632 as shown in subsequent FIG. 6B) back from the third vertical opening 631 to form a plurality of first lateral recesses 642. In the example embodiment shown in FIG. 6A, the first lateral distance (e.g., first lateral distance 632 in FIG. 6B) can be half of the lateral width of an elongated vertical column (e.g., elongated vertical column 521 as shown in FIG. 5A) such that in combination the plurality of first lateral recesses 642 extending from the third vertical openings 631 which extend from the second pair of second vertical openings 527-3, 527-4, form an opening all around the channel material 615 in the vertical plane of the second vertical opening 627. FIG. 6A also illustrates the second vertical openings 627-3 extending completely around the vertical stack 601 to form a trench in the first oxide material 625 along the surface of the vertical stack 601.

FIG. 6B is a cross sectional view, taken along cut-line D-D′ in FIG. 5A, showing another view of the semiconductor structure at a particular time in the semiconductor fabrication process. In the example embodiment shown in the example of FIG. 6B, the method comprises selectively etching the first sacrificial material a first lateral distance 632 back from the third vertical opening 631 to form a plurality of first lateral recesses 642. In the example embodiment shown in FIG. 6B, the first lateral distance 632 can be half of the lateral width of an elongated vertical column (e.g., elongated vertical column 521 as shown in FIG. 5A) such that a portion of the of the first sacrificial material 617 remains in the vertical plane of the second vertical opening 627 between the plurality of first lateral recesses 642 extending from each third vertical opening 631, which extend from the first pair of second vertical openings 527-1, 527-2 in FIG. 5B, and the plurality of first lateral recesses 642 extending from each other third vertical opening 631 extending from the first pair of second vertical openings 527-, 527-2 in FIG. 5B. In other words, an opening partially wraps around the channel material 615. FIG. 6B also illustrates the second vertical openings 627-3 extending completely around the vertical stack 601 to form a trench in the first oxide material 625 along the surface of the vertical stack 601.

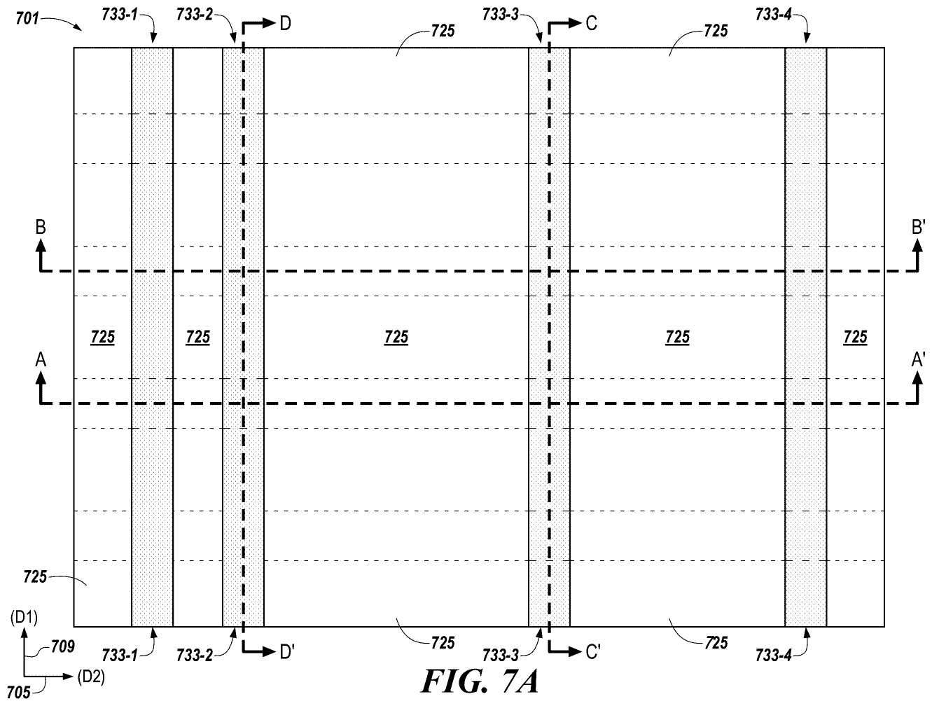

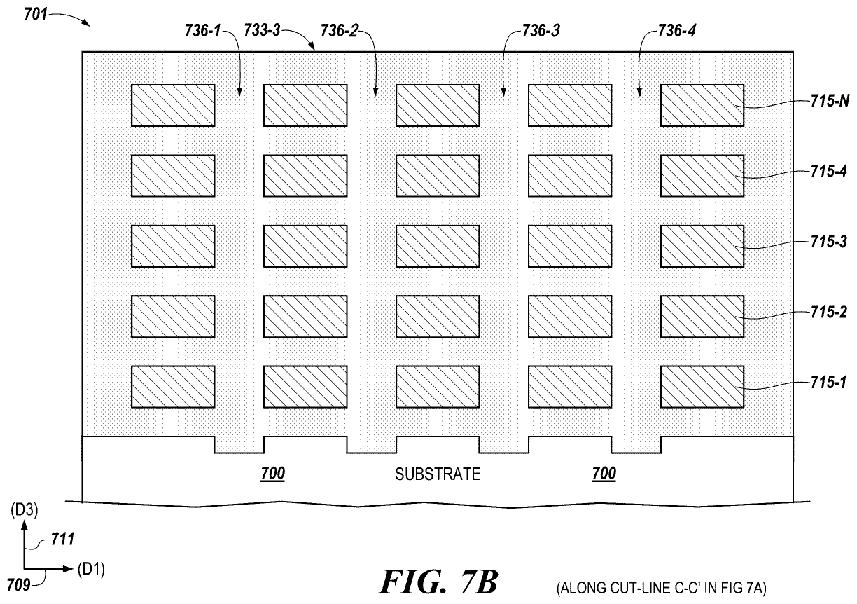

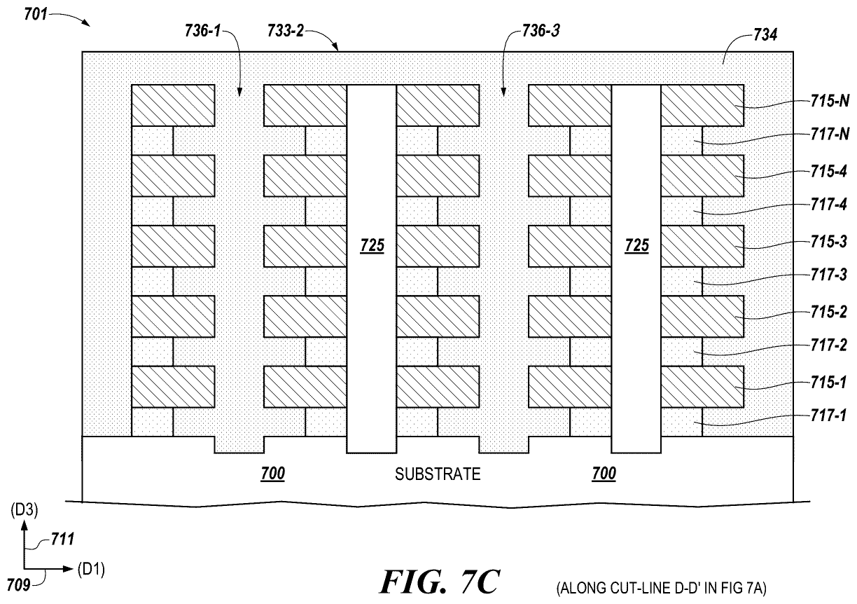

FIG. 7A illustrates an example method, at another stage of a semiconductor fabrication process, for forming arrays of vertically stacked memory cells, having horizontally oriented access devices and vertically oriented access lines, such as illustrated in FIG. 1A and FIG. 1B, and in accordance with a number of embodiments of the present disclosure. FIG. 7A illustrates a top down view of a semiconductor structure at a particular point in time in a semiconductor fabrication process, according to one or more embodiments. In the example embodiment shown in FIG. 7A, the method comprises depositing a nitride material (e.g. Si₃N₄) to form a plurality of nitride lattice support structures 733. In the example embodiment shown in FIG. 7A, the nitride material can be deposited to fill the plurality of first lateral recesses (e.g., first lateral recesses 642 as shown in FIG. 6A and FIG. 6B), the plurality of third vertical openings (e.g., third vertical openings 631 as shown in FIG. 6A and FIG. 6B), and the plurality of second vertical openings (e.g., second vertical openings 627 as shown in FIG. 6A and FIG. 6B) in through the second sacrificial material 725 and the vertical stack 701. The nitride material can be a silicon nitride material, and/or a silicon oxynitride material, or any other suitable dielectric material with rigidity similar to Si₃N₄. Embodiments, however, are not limited to these examples. The nitride material can be deposited by atomic layer deposition, spin on deposition, chemical vapor deposition, or any other suitable method of material deposition. In the example embodiment shown in FIG. 7A, the plurality of nitride lattice support structure 733 include a first pair of nitride lattice support structures 733-1, 733-2 and a second pair of nitride lattice support structures 733-3, 733-4. The first pair of nitride lattice support structures 733-1, 733-2 are formed in the first pair of second vertical openings, (e.g., second vertical openings 527-1, 527-2) such that the first pair of nitride lattice support structures 733-1, 733-2 are horizontally positioned in the vertical stack 701 such that the first pair of nitride lattice support structures 733-1, 733-2 are adjacent to opposing sides of where a capacitor top electrode, (e.g., capacitor top electrode 1867 as shown in FIG. 18B) exit will be formed. The second pair of nitride lattice support structures 733-3, 733-,4, formed in the second pair of second vertical openings, (e.g., 527-3, 527-4) such that the second pair of nitride lattice support structures 733-1,733-2 are horizontally positioned in the vertical stack 701 such that the second pair of nitride lattice support structures 733-3, 733-4, are adjacent to opposing sides of where an access device will be formed, (e.g., gate metal runners 1843 and digit side contacts 1869 as shown in FIG. 18B).

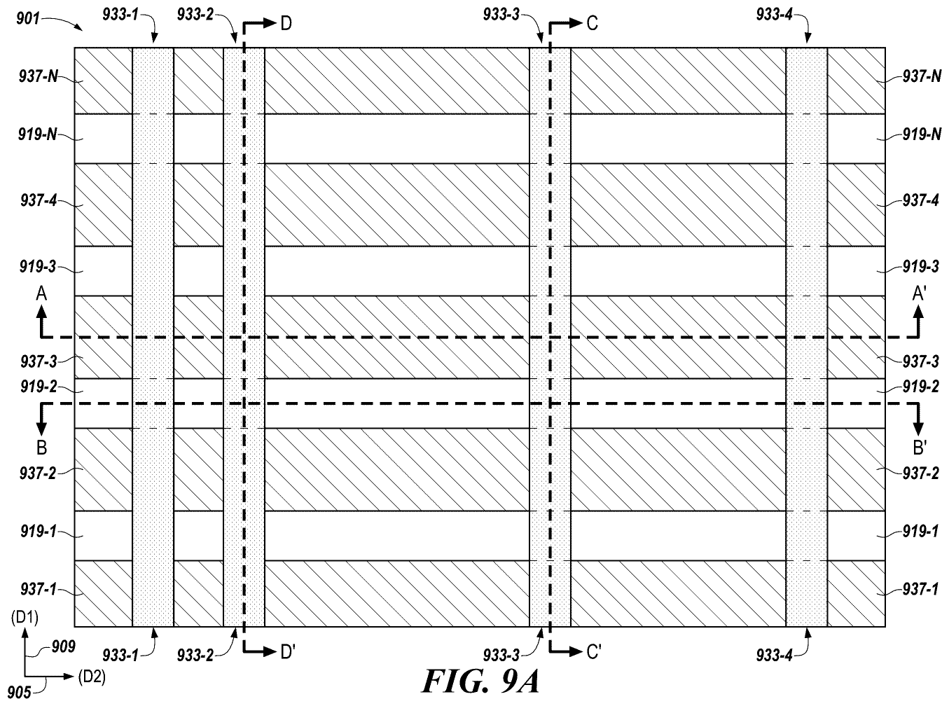

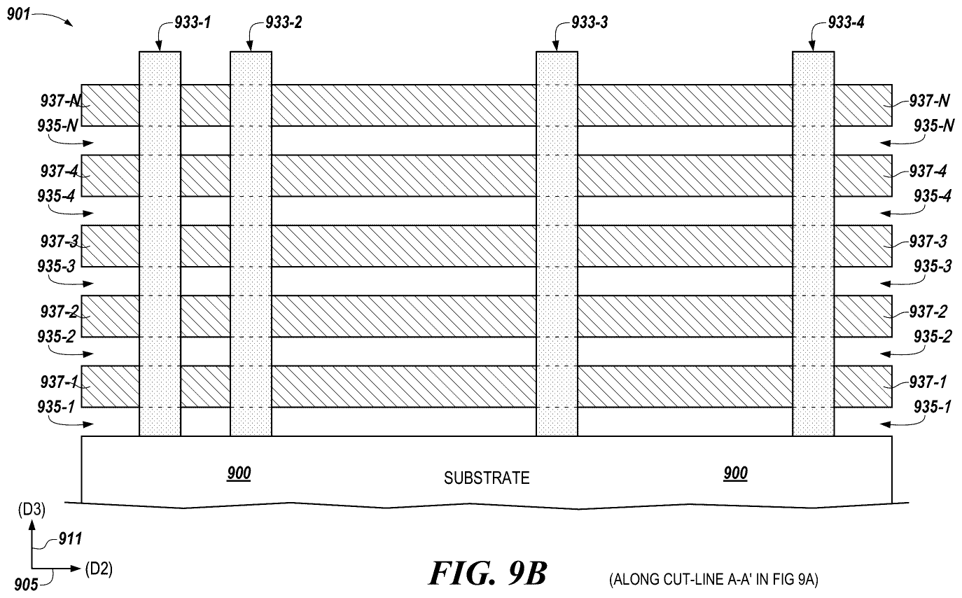

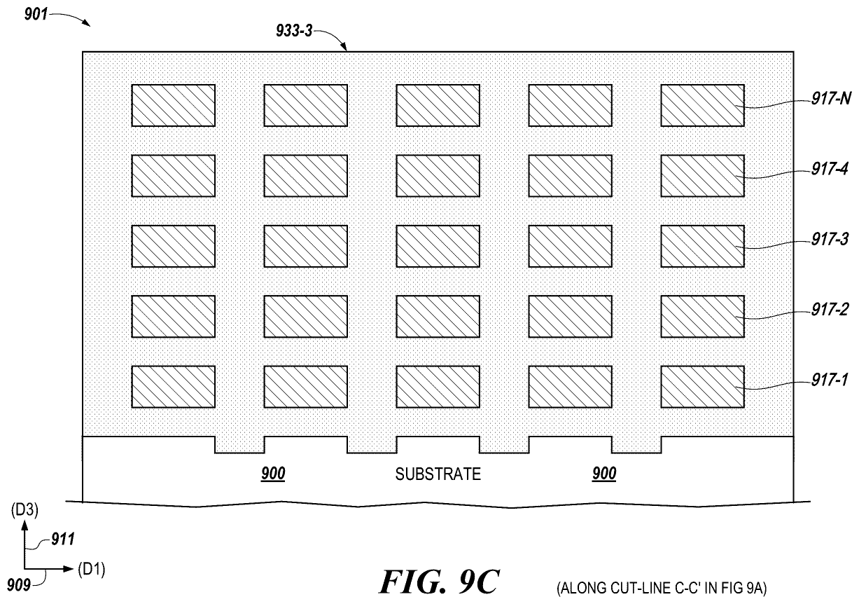

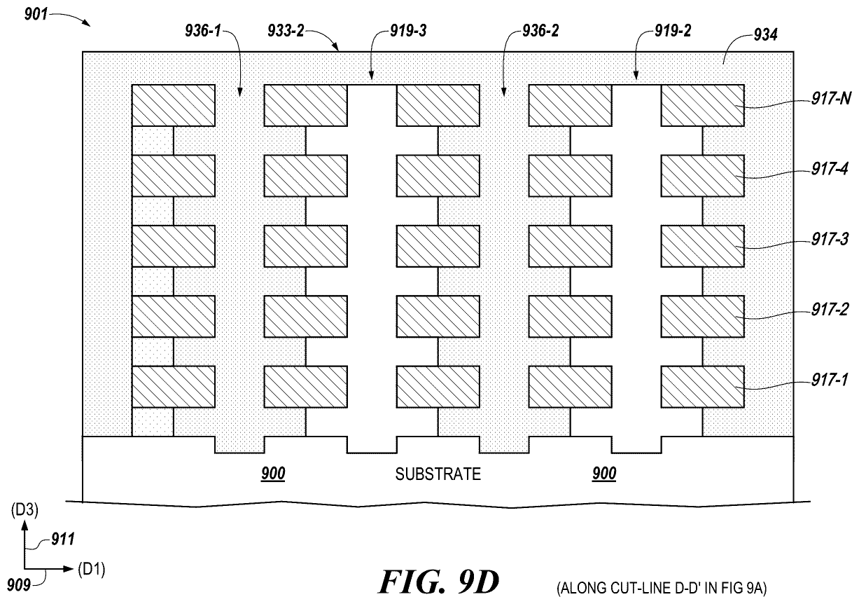

FIG. 7B is a cross sectional view, taken along cut-line C-C′ in FIG. 7A, showing another view of the semiconductor structure at a particular time in the semiconductor fabrication process. FIG. 7B shows a cross sectional view of a nitride lattice support structure 733-3 of the second pair of nitride lattice support structures 733-3, 733-4. FIG. 7B illustrates vertical portions 736 of the second pair of nitride lattice support structures 733-3, 733-4 wrap around the channel material 715 of that will become each channel material channel (e.g., channel material channel 937 as shown in subsequent FIG. 9A) and can help provide structural support to the vertical stack 701 and to protect future array devices, (e.g., gate metal runners 1843 and digit side contacts 1869 as shown in FIG. 18B) from the double sided capacitor formation process.

FIG. 7C is a cross sectional view, taken along cut-line D-D′ in FIG. 7A, showing another view of the semiconductor structure at a particular time in the semiconductor fabrication process. FIG. 7C shows a cross sectional view of a nitride lattice support structure 733-2 of the first pair of nitride lattice support structures 733-1,733-2. FIG. 7C illustrates vertical portions 736 of the first pair of nitride lattice support structures 733-1, 733-2, partially wrap around the channel material 815 of each channel material channel (e.g., channel material channel 937 as shown in subsequent FIG. 9A) leaving room for the double sided capacitor formation process while providing structural support to the array 701.

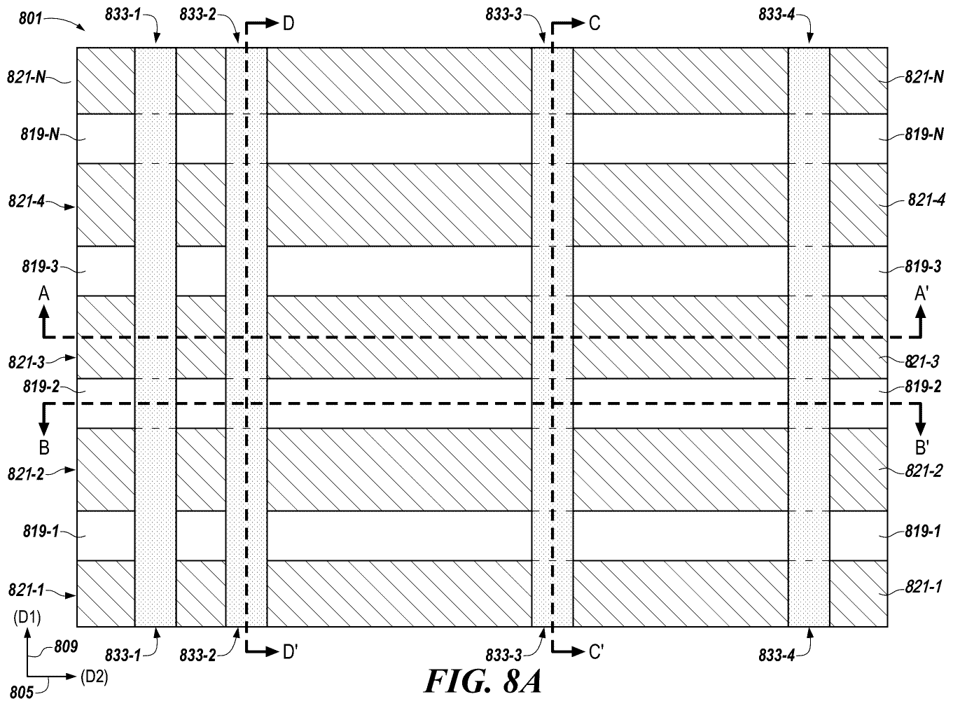

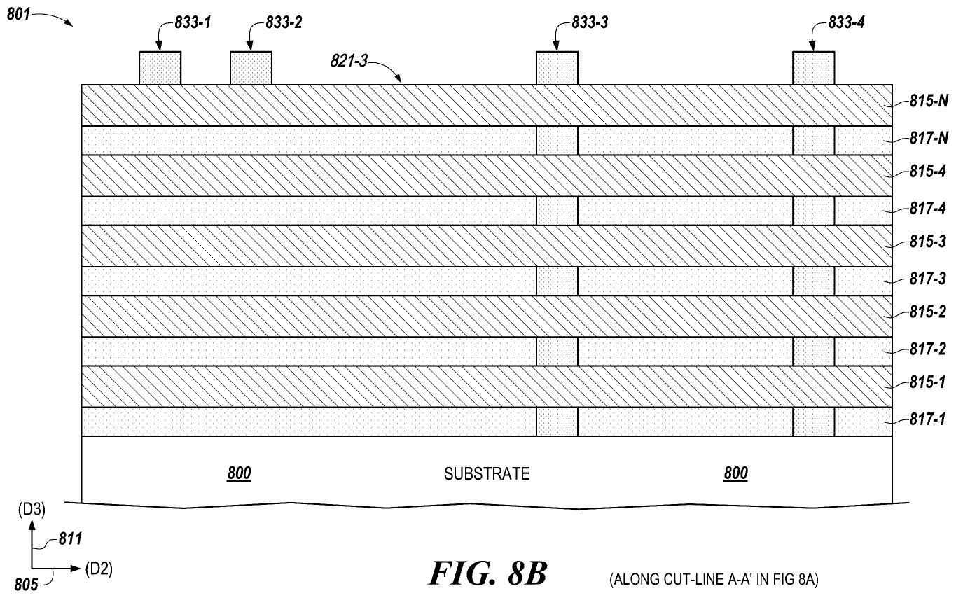

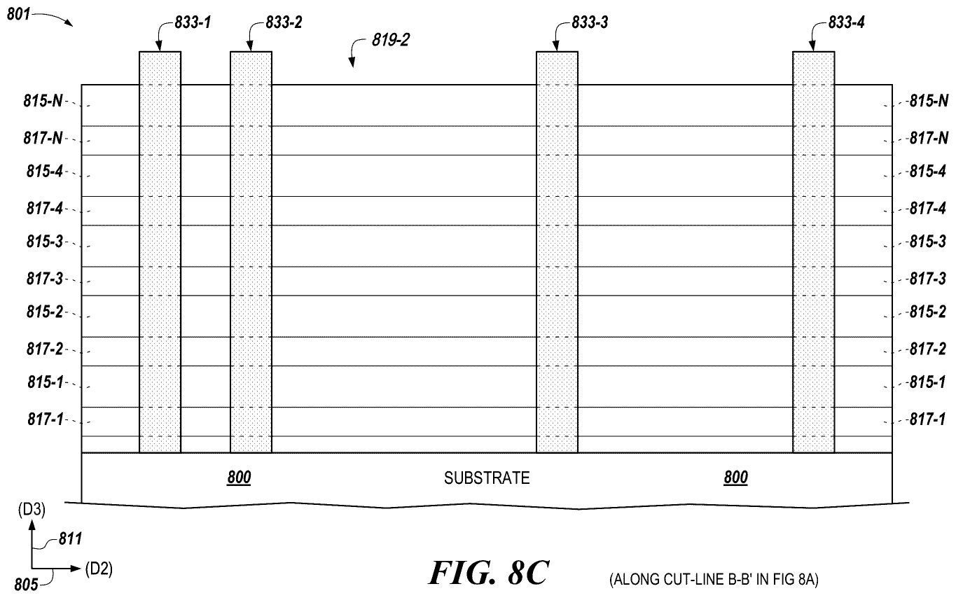

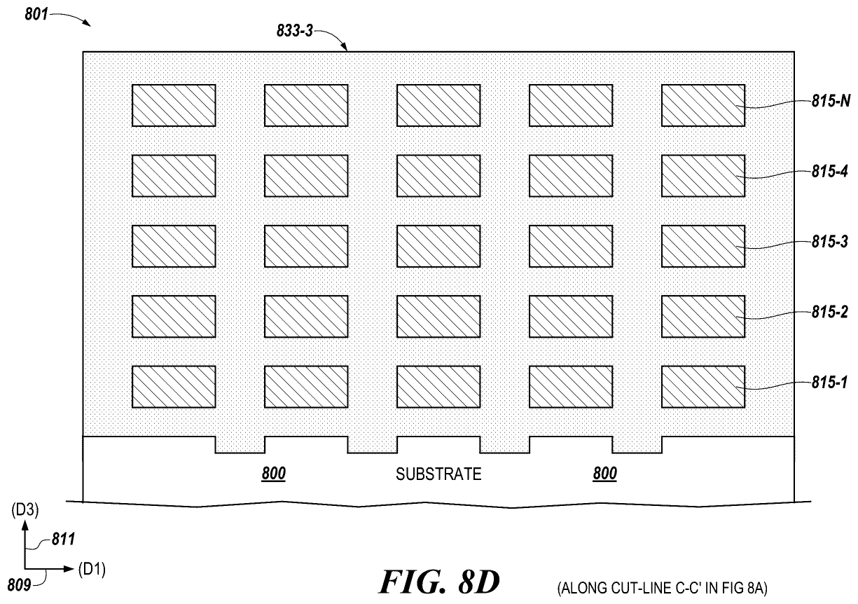

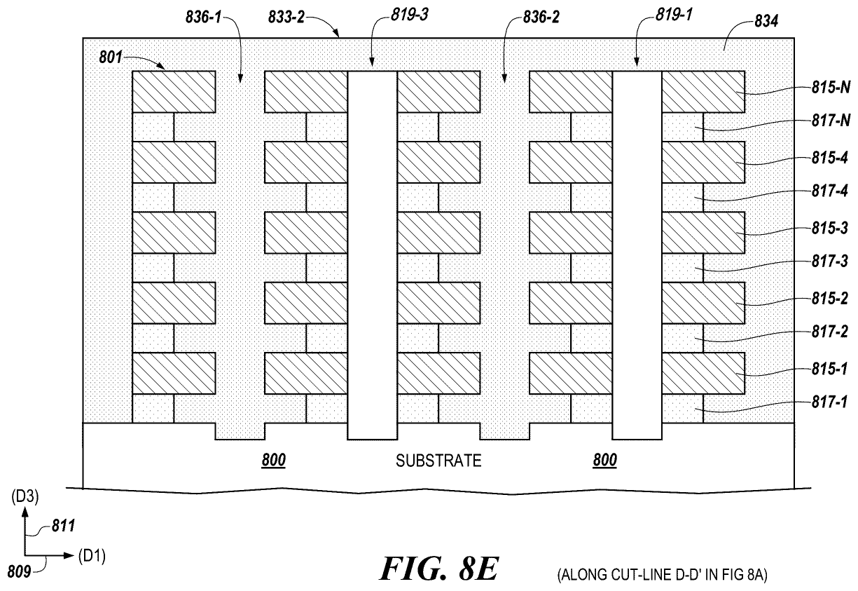

FIG. 8A illustrates an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 8A illustrates a top down view of a semiconductor structure at a particular point in time in a semiconductor fabrication process, according to one or more embodiments. In the example embodiment shown in FIG. 8A the method comprises selectively removing the second sacrificial material (e.g., second sacrificial material 725 in FIG. 7A) to uncover the elongated vertical columns 821 of the vertical stack 801 and the plurality of nitride lattice support structures 833, and to reopen the first vertical openings 819.

FIG. 8B is a cross sectional view, taken along cut-line A-A′ in FIG. 8A, showing another view of the semiconductor structure at a particular time in the semiconductor fabrication process. FIG. 8B shows a cross section along the first horizontal direction (D2) 805 through an elongated vertical stack 821-3 of an example embodiment. FIG. 8B illustrates the alternating layers of channel material 815 and first sacrificial material 817 in the vertical stack 801. The example embodiment also shows the second pair of nitride lattice support structures 833-3, 833-4, extending between the layers of channel material 815, as well as the remaining sacrificial material 817 between the first pair of nitride lattice support structures 833-1, 833-2.

FIG. 8C is a cross sectional view, taken along cut-line B-B′ in FIG. 8A, showing another view of the semiconductor structure at a particular time in the semiconductor fabrication process. FIG. 8C shows a cross section along the first horizontal direction (D2) 805 through a first vertical opening 819-2. FIG. 8C illustrates the plurality of nitride lattice support structures 833 extending vertically through the first vertical opening 819-2 along the alternating layers of channel material 815 and first sacrificial material 817 in the vertical stack 801.

FIG. 8D is a cross sectional view, taken along cut-line C-C′ in FIG. 8A, showing another view of the semiconductor structure at a particular time in the semiconductor fabrication process. FIG. 8D shows a cross section along the first lateral direction (D1) of a nitride lattice support structure 833-3 of the second pair of nitride lattice support structures 833-3, 833-4 of the vertical stack 801. FIG. 8D illustrates the second pair of nitride lattice support structures 833-3, 833-4 wrap around the channel material 815 of what will become a plurality of channel material channels (e.g., channel material channel 937 as shown in FIG. 9A).

FIG. 8E is a cross sectional view, taken along cut-line D-D′ in FIG. 8A, showing another view of the semiconductor structure at a particular time in the semiconductor fabrication process. FIG. 8E shows a cross section along the first lateral direction (D1) of a nitride lattice support structure 833-2 of the first pair of nitride lattice support structures 833-1, 833-2 with a lateral support structure portion 834 extending laterally across the top of the vertical stack 801 and a plurality of vertical support structure portions 836 extending vertically down from the lateral support structure portion 834 to the substrate 800. FIG. 8E illustrates the first pair of nitride lattice support structures 833-1, 833-2, partially wrap around the channel material 815 of each channel material channel, (e.g., channel material channel 937 as shown in FIG. 9A.) The example embodiment shown in FIG. 8E also shows the opening through the first pair of nitride lattice support structures 833-1, 833-2 along a number of the first vertical openings 819-1, 819-3 left by the removal of the second sacrificial material (e.g., second sacrificial material 725 as shown in FIG. 7C) leaving room for the double sided capacitor formation process. FIG. 8E also shows the remaining first sacrificial material 817 which is analogous to first sacrificial material 217, 317, 417, 517, 617, and 717 in FIGS. 2 to 7C.

FIG. 9A illustrates an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 9A illustrates a top down view of a semiconductor structure at a particular point in time in a semiconductor fabrication process, according to one or more embodiments. In the example embodiment shown in FIG. 9A the method comprises selectively removing the first sacrificial material (e.g., first sacrificial material 817 as shown in FIG. 8B) to form a plurality of first horizontal openings (e.g., first horizontal openings 935 as shown in subsequent FIG. 9B), extending predominantly in the first horizontal direction (D2) 905, shaping the channel material (e.g., channel material 815 as shown in FIG. 8B) into a plurality of channel material channels 937 separated by the plurality of first vertical openings 919, and supported by the plurality of nitride lattice support structures 933. The material can be removed by a process, or any other suitable process as will be appreciated.

FIG. 9B is a cross sectional view, taken along cut-line A-A′ in FIG. 9A, showing another view of the semiconductor structure at a particular time in the semiconductor fabrication process. FIG. 9B illustrates the plurality of channel material channels 937 separated by the plurality of first horizontal openings 935 and supported by the plurality of nitride lattice support structures 933.

FIG. 9C is a cross sectional view, taken along cut-line C-C′ in FIG. 9A, showing another view of the semiconductor structure at a particular time in the semiconductor fabrication process. FIG. 9C illustrates the second pair of nitride lattice support structures 933-3, 933-4 wrapping around the each channel material channel 937, which can help provide structural support to the array and to protect future array devices, (e.g., gate metal runners 1843 and digit side contacts 1869 as shown in FIG. 18B) from the double sided capacitor formation process.

FIG. 9D is a cross sectional view, taken along cut-line D-D′ in FIG. 9A, showing another view of the semiconductor structure at a particular time in the semiconductor fabrication process. FIG. 9D illustrates vertical portions 936 of the first pair of nitride lattice support structures 933-1, 933-2, partially wrapping around each channel material channel 937. FIG. 9D also shows the opening left by the first vertical opening 919 and the first horizontal openings 935, which can provide room for a double sided capacitor formation process while providing structural support to the array.

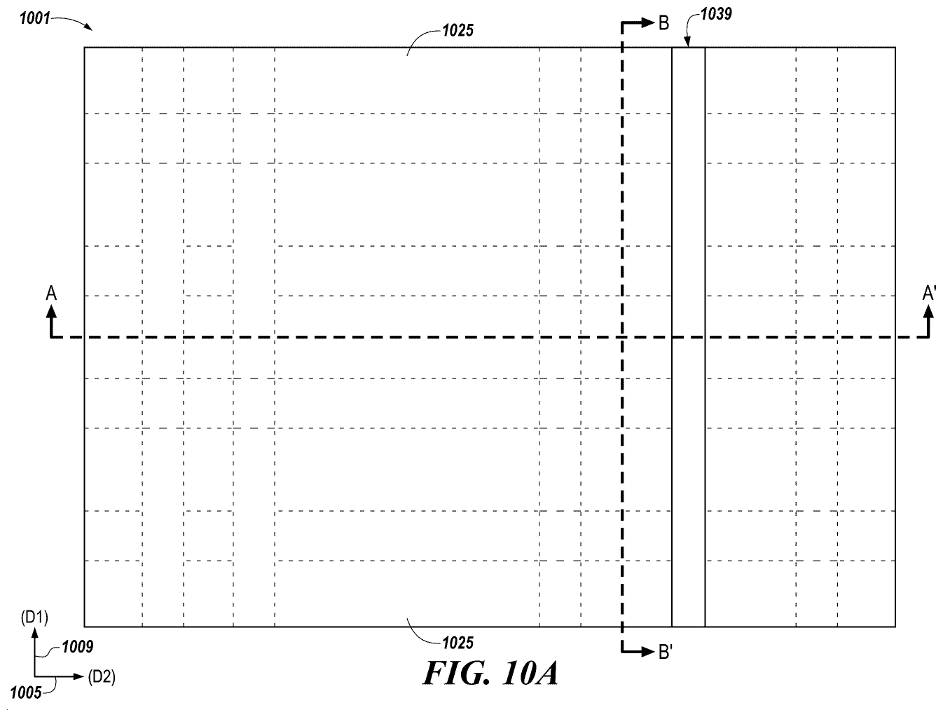

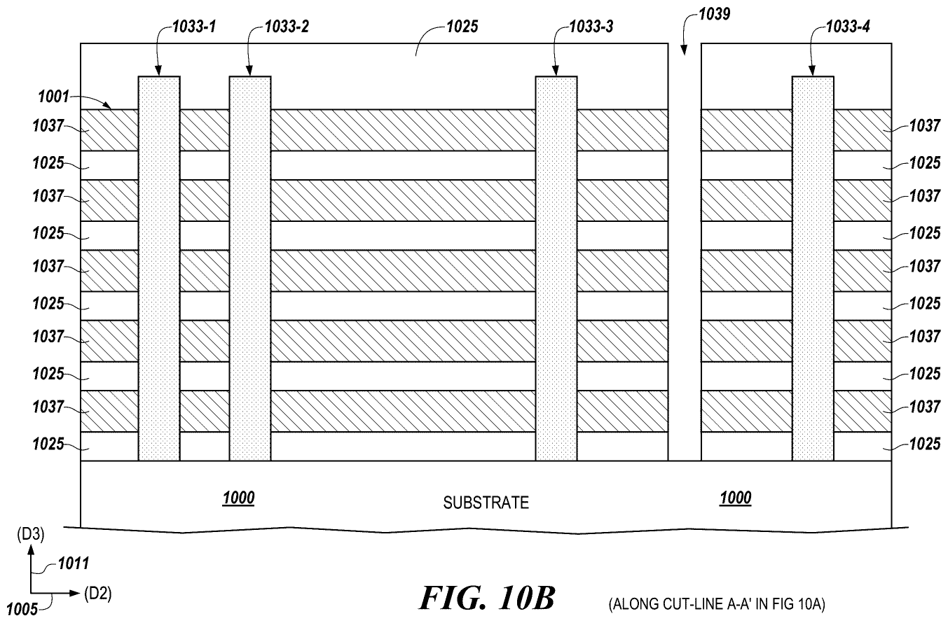

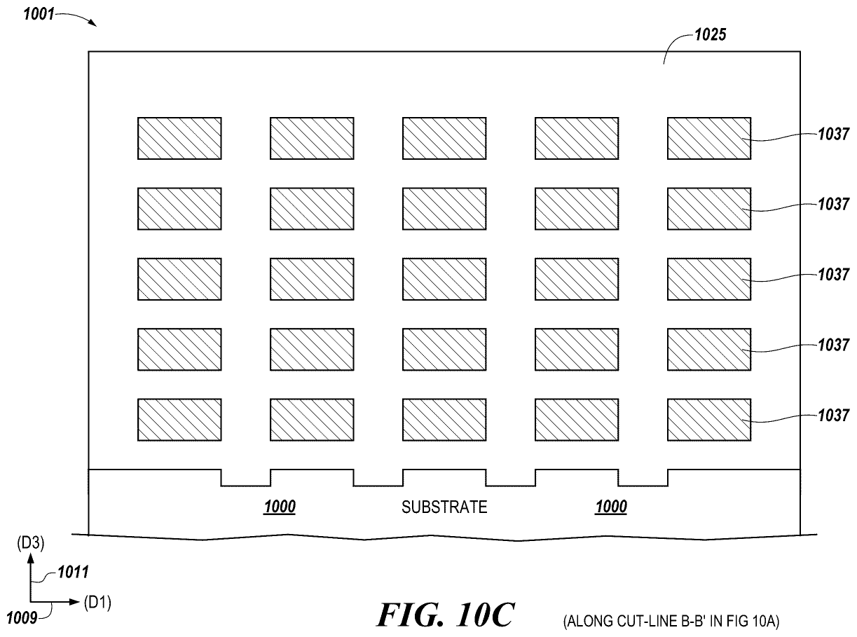

FIG. 10A illustrates an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 10A illustrates a top down view of a semiconductor structure at a particular point in time in a semiconductor fabrication process, according to one or more embodiments. In one example embodiment, as depicted by FIG. 10A the method comprises depositing additional second sacrificial material 1025 to fill the array, (e.g., backfilling the array with an oxide material such as SiO₂) and planarizing the array, such as by chemical mechanical planarization, or other suitable method to planarize the second sacrificial material 1025 as will be appreciated. A fourth vertical opening 1039 having a first lateral direction (D1) 1009 and a first horizontal direction (D2) 1005, through the vertical stack to the substrate (e.g., substrate 1000 as shown in subsequent FIG. 10B) can then be formed in the planarized vertical stack 1001 to prepare the array for device gate or contact formation. In one example embodiment, as shown in FIG. 10A, the fourth vertical openings 1039 can be horizontally disposed on the vertical stack 1001 between the second pair of nitride lattice support structures (e.g., nitride lattice support structures 1033-3, 1033-4 as shown in subsequent FIG. 10B) and extends predominantly in the first lateral direction (D1) 1009. The plurality of first vertical openings 319 may be formed using dry etching techniques.

FIG. 10B is a cross sectional view, taken along cut-line A-A′ in FIG. 10A, showing another view of the semiconductor structure at a particular time in the semiconductor fabrication process. FIG. 10B illustrates one example embodiment in which the fourth vertical opening 1039 splits and exposes the ends of the plurality of channel material channels 1037 and second sacrificial material 1025 surrounding the plurality of channel material channels 1037. In one example embodiment, as shown in FIG. 10A, the fourth vertical openings 1039 is horizontally disposed on the vertical stack 1001 between the second pair of nitride lattice support structures 1033-3, 1033-4.

FIG. 10C is a cross sectional view, taken along cut-line B-B′ in FIG. 10A, showing another view of the semiconductor structure at a particular time in the semiconductor fabrication process. FIG. 10C shows a cross section along the lateral direction 1005 between a first nitride lattice support structure (e.g., nitride lattice support structure 1033-3 as shown in FIG. 10B), of the second pair of nitride lattice support structures (e.g., nitride lattice support structures 1033-3, 1033-4 as shown in FIG. 10B), and the fourth vertical opening (e.g., fourth vertical opening 1039 as shown in FIG. 10B). FIG. 10C illustrates the plurality of channel material channels 1037 surrounded by the second sacrificial material 1025.

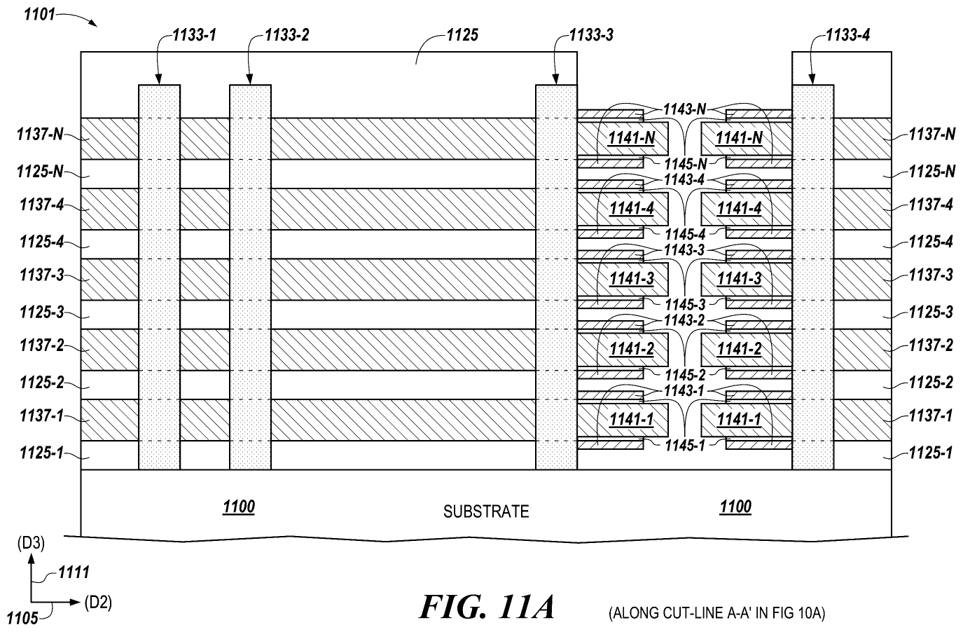

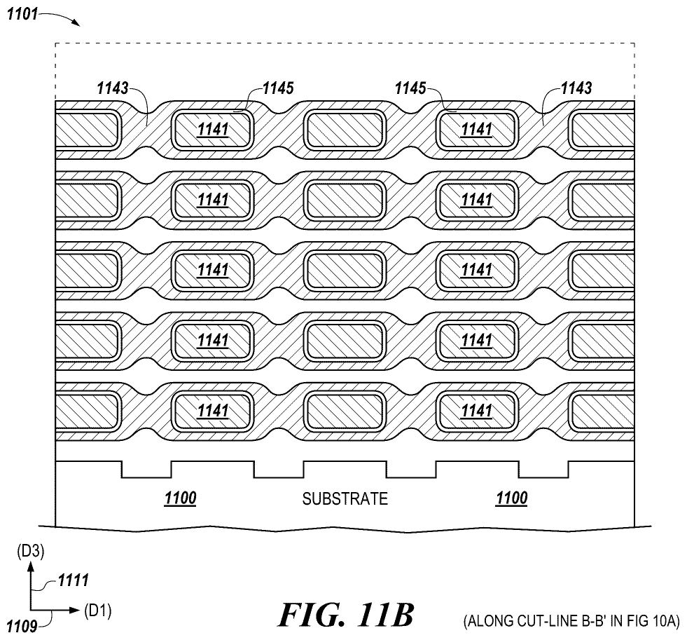

FIG. 11A is a cross sectional view, taken along cut-line A-A′ in FIG. 10A, showing another view of the semiconductor structure at a particular time in the semiconductor fabrication process. In one example embodiment as, as depicted by FIG. 11A, the method comprises forming an access device between the second pair of nitride lattice support structures 1133-3, 1133-4. Forming the access device can include selectively etching the second sacrificial material 1125 between the second pair of nitride lattice support structures 1133-3, 1133-4 to expose the channel material channel end portion 1141. Forming the access device can further include corner rounding of the channel material channel 1137, forming channel all around gate oxide 1145, and forming a plurality of gate metal runners 1143 extending predominantly in the first lateral direction (D1) 1109 and wrapping around the plurality of channel material channel end portions 1141. Corner rounding of the channel material channel forming the channel all around gate oxide 1145 can include oxidation of the channel material channel end portions 1141, oxide removal, and re-oxidation of the channel material channel end portions 1141. The gate metal runners 1143 can be a titanium nitride material, a titanium nitride tungsten mixture material, or any other gate all around gate metal as will be appreciated by a person of ordinary skill in the art. In some example embodiments (not shown) the semiconductor fabrication process can include photo resist masking, or other hard-masking (e.g., carbon, carbon based, or other hard mask materials), and a dry or wet etch to selectively remove at least a portion of the gate metal runners 1143 and the channel all around gate oxide 1145 to expose the channel material channel 1137 for future digit line contact formation.

FIG. 11B is a cross sectional view, taken along cut-line B-B′ in FIG. 10A, showing another view of the semiconductor structure at a particular time in the semiconductor fabrication process. FIG. 11B shows a cross section of the vertical stack 1101 and illustrates the gate metal runners 1143 around each channel material channel end portion 1141 and separated from the plurality of channel material channel end portions 1141 by the channel all around gate oxide 1145 wrapped around each channel material channel end portion 1141. In some embodiments the gate metal runners 1143 can be horizontal access lines (e.g., wordlines). In some embodiments stair-case contacts (not shown) can be formed at a die plan edge. In some embodiments the stair-case contacts access or connect to the horizontally oriented access lines (e.g., gate metal runners 1143). In some embodiments the stair-case contacts access or connect to horizontally oriented digit lines (not shown).

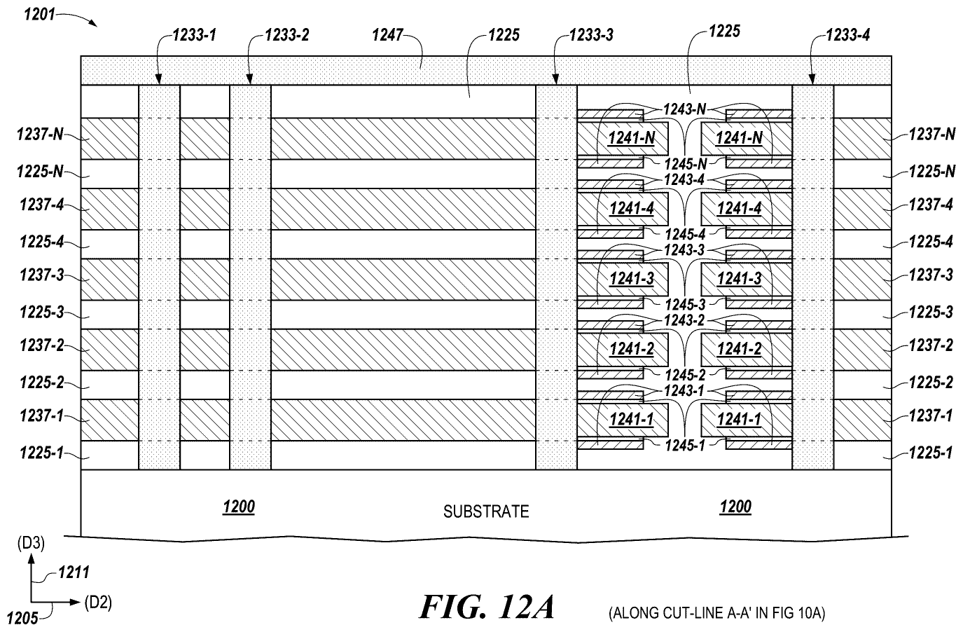

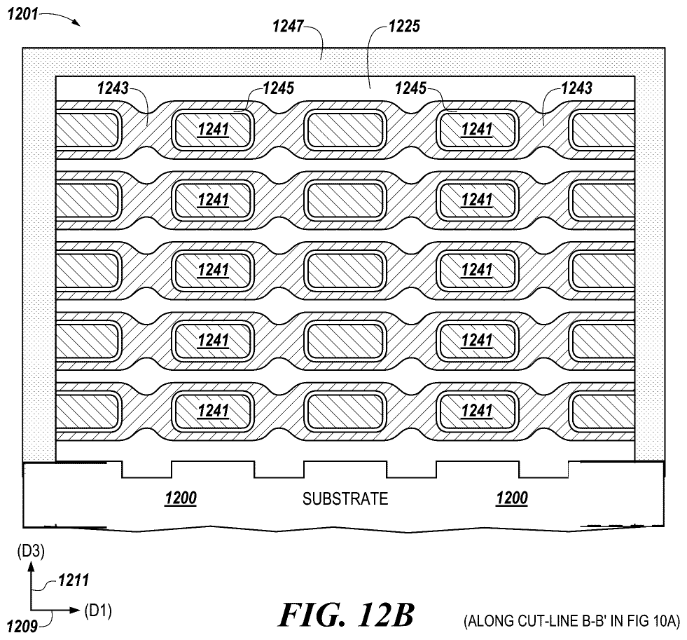

FIG. 12A is a cross sectional view, taken along cut-line A-A′ in FIG. 10A, showing another view of the semiconductor structure at a particular time in the semiconductor fabrication process. In one example embodiment as, as depicted by FIG. 12A, the method comprises depositing additional second sacrificial material 1225 to fill the space between the second pair of nitride material support structures 1233-3, 1233-4 and planarizing the array. In the example embodiment, the method further comprises depositing a layer of nitride material (e.g., Si₃N₄) on the vertical stack 1201 and planarizing the nitride material, through a process such as CMP, to form a nitride wall or nitride well wall 1247. The nitride well wall 1247 can connect the plurality of nitride lattice support structures 1233, providing support and scaling the array. The nitride well wall 1247 can wrap around the vertical stack 1201 (wrap around not shown). FIG. 12A also shows the plurality of channel material channel end portions 1241, gate metal runners 1243, and channel all around gate oxide 1245 between the second pair of nitride lattice support structures 1233-3, 1233-4, surrounded by second sacrificial material 1225, and covered by the nitride well wall 1247.

FIG. 12B is a cross sectional view, taken along cut-line B-B′ in FIG. 10A, showing another view of the semiconductor structure at a particular time in the semiconductor fabrication process. FIG. 12B illustrates a cross section of the vertical stack 1201 and illustrates the nitride well wall 1247 covering the vertical stack 1201 which includes the second sacrificial material 1225 surrounding the gate metal runners 1243 around each channel material channel end portion 1241 and separated from the plurality of channel material channel end portions 1241 by a channel all around gate oxide 1245 wrapped around each channel material channel end portion 1241.

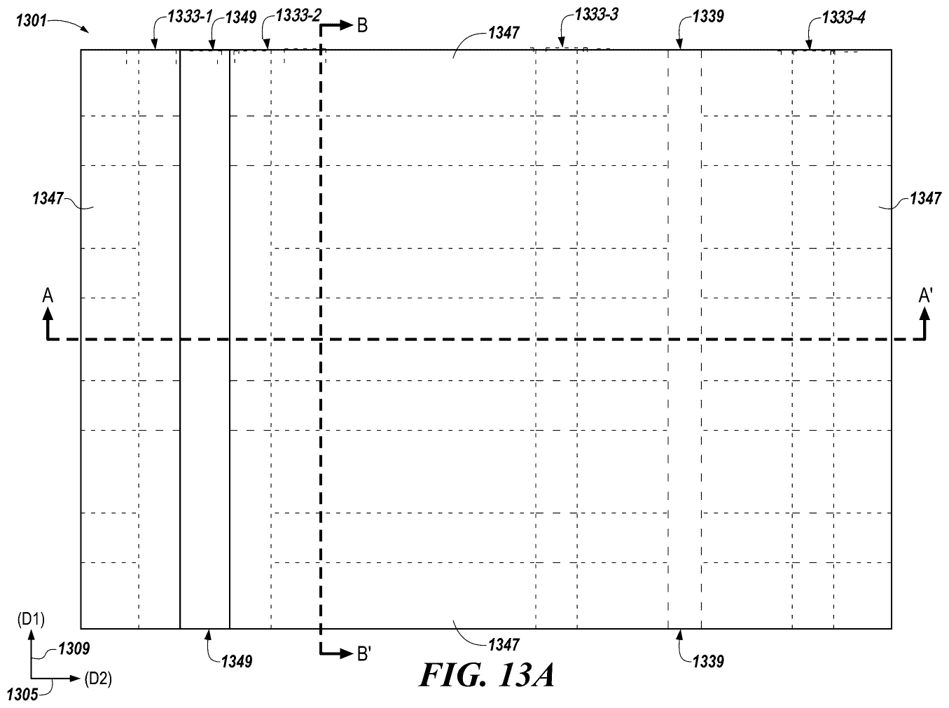

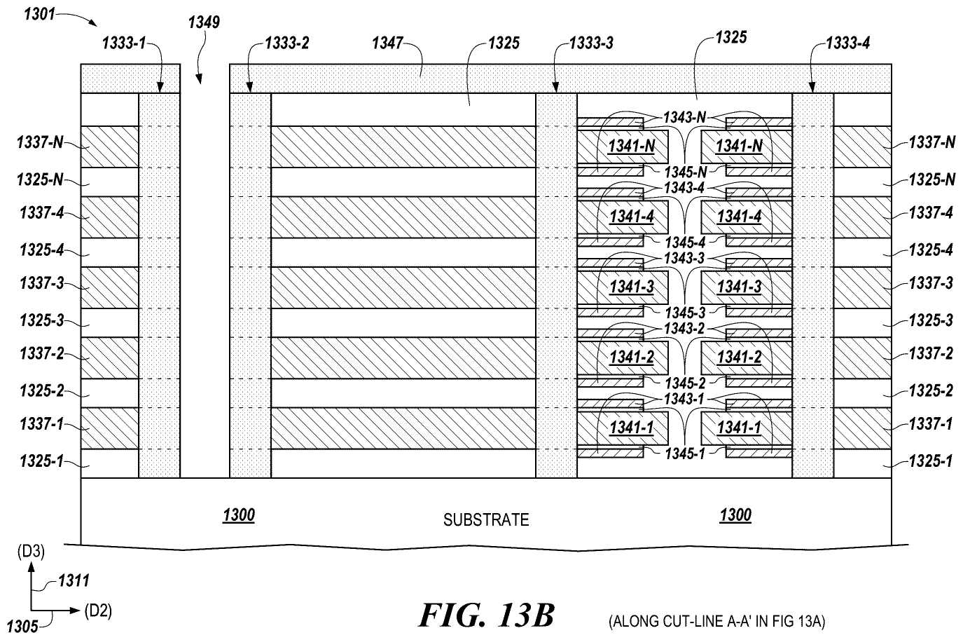

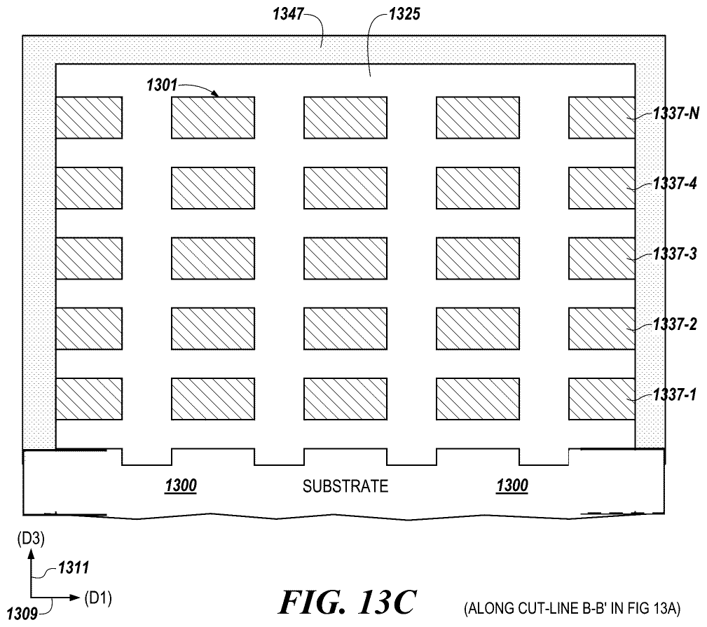

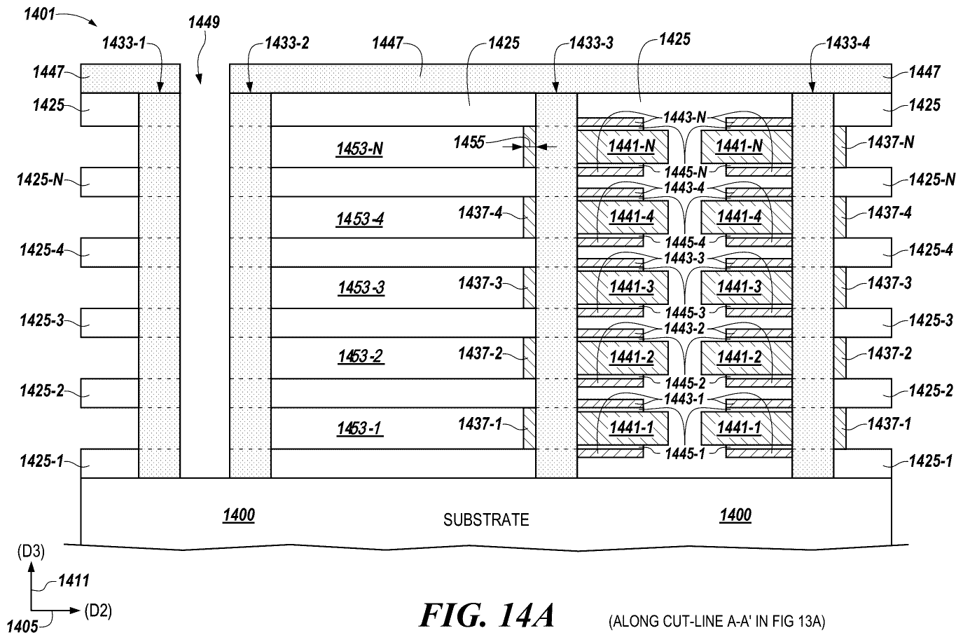

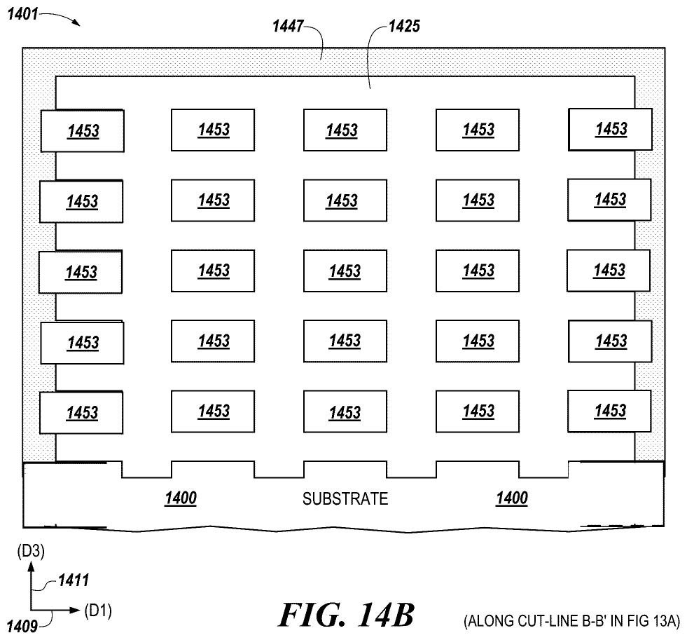

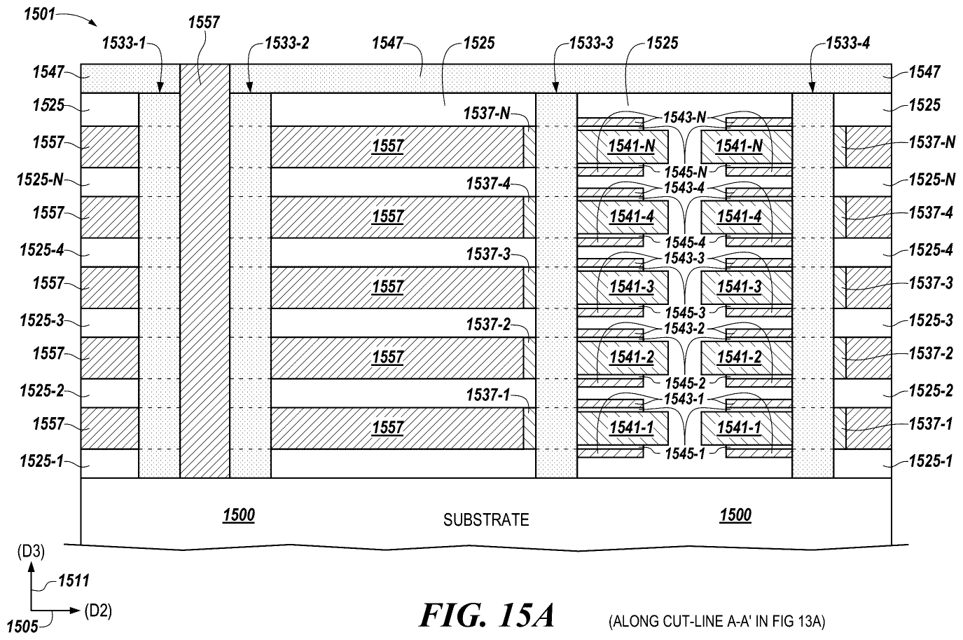

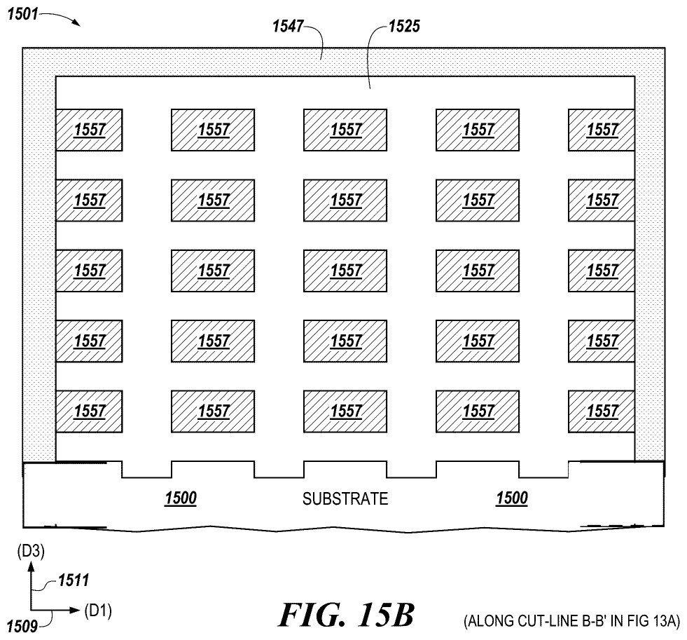

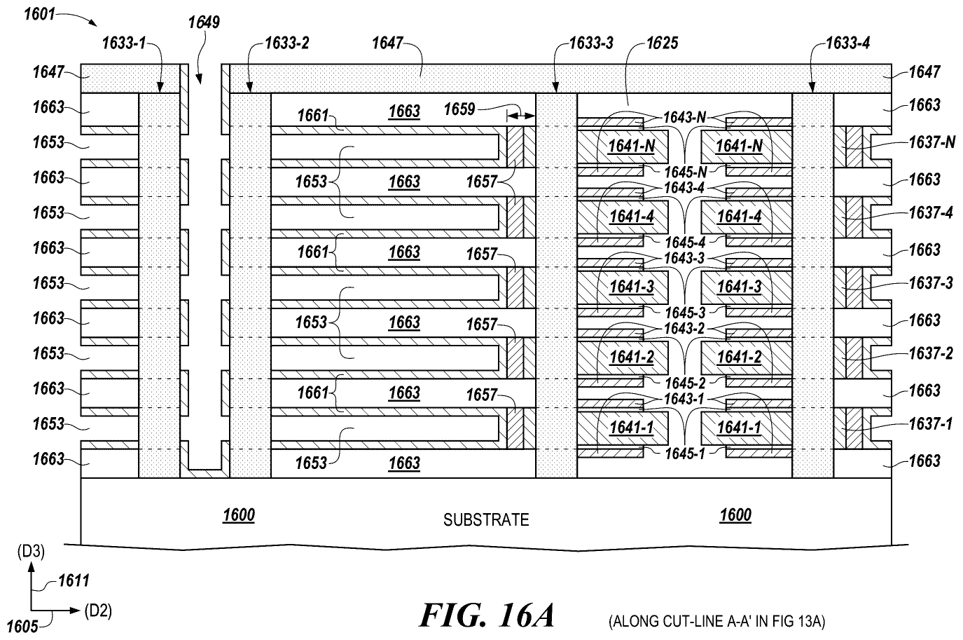

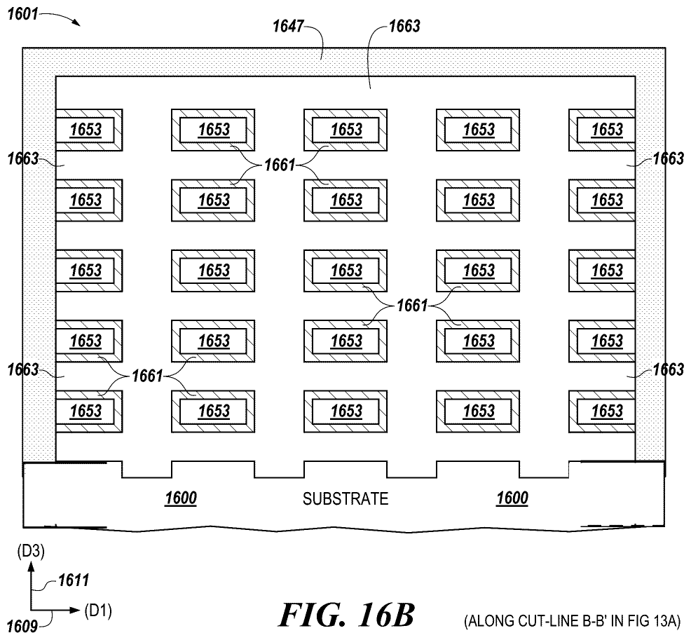

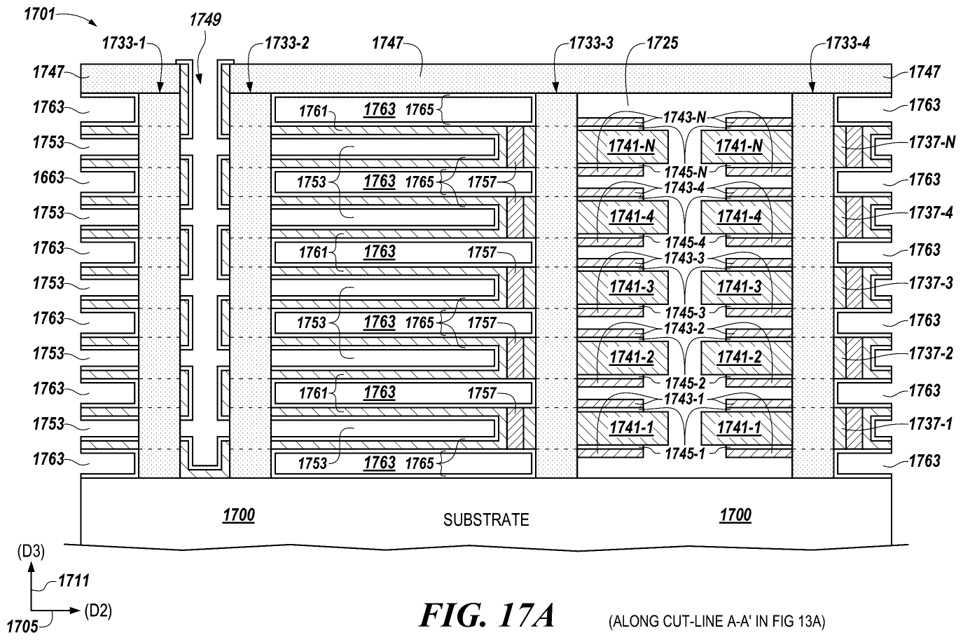

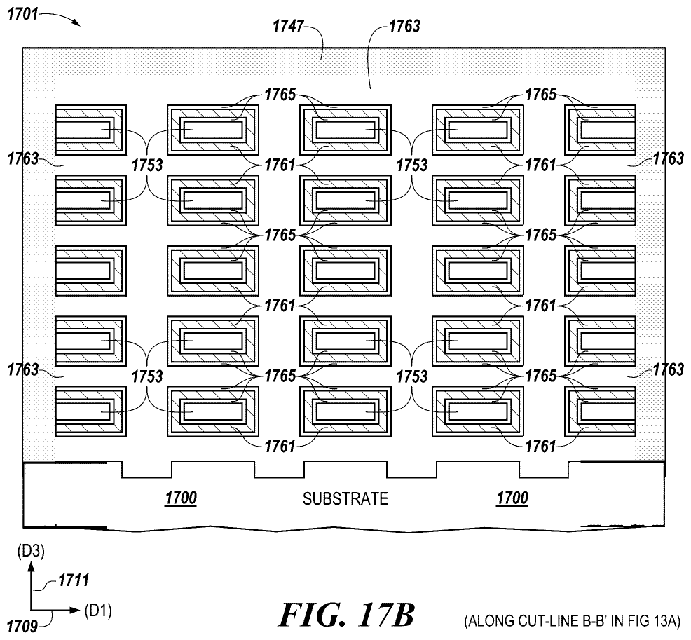

FIG. 13A illustrates an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 13A illustrates a top down view of a semiconductor structure at a particular point in time in a semiconductor fabrication process, according to one or more embodiments. In one example embodiment, as depicted by FIG. 13A, the method includes forming a fifth vertical opening 1349 having a first lateral direction (D1) 1309 and a first horizontal direction (D2) 1305, through the nitride well wall 1347 and the vertical stack 1301 to the substrate 1300. The fifth vertical opening 1349 horizontally disposed on the vertical stack 1301 between a first nitride lattice support structure 1333-1 of the first pair of nitride lattice support structures 1333-1, 1333-2 and a second nitride lattice support structure 1333-2 of the first pair of nitride lattice support structures 1333-1, 1333-2 and extending predominantly in the first lateral direction (D1) 1309.

FIG. 13B is a cross sectional view, taken along cut-line A-A′ in FIG. 13A, showing another view of the semiconductor structure at a particular time in the semiconductor fabrication process. FIG. 13B illustrates the fifth vertical opening 1349 extending between the first pair of nitride lattice support structures 1333-1, 1333-2, exposing the plurality of channel material channels 1337 and second sacrificial material 1325 which extends through the nitride lattice support structures. In the example embodiment he fifth vertical opening 1349 opens up the cell side of the vertical stack 1301 to prepare for cell side contact and storage node, (e.g., capacitor) formation. FIG. 13B also shows the plurality of channel material channel end portions 1341, gate metal runners 1343, and channel all around gate oxide 1345 between the second pair of nitride lattice support structures 1333-3, 1333-4, surrounded by second sacrificial material 1325, and covered by the nitride well wall 1347.

FIG. 13C is a cross sectional view, taken along cut-line B-B′ in FIG. 13A, showing another view of the semiconductor structure at a particular time in the semiconductor fabrication process. FIG. 13C shows a cross section of the example embodiment along the first lateral direction (D1) 1309 between the first pair of nitride lattice support structures (e.g., first pair of nitride lattice support structures 1333-1, 1333-2 as shown in FIG. 13B) and the second pair of nitride lattice support structures (e.g., second pair of nitride lattice support structures 1333-3, 1333-4 as shown in FIG. 13B). The example embodiment in FIG. 13C illustrates the plurality of channel material channels 1337 surrounded by the second sacrificial material 1325, and the nitride well wall 1347 disposed on the vertical stack 1301.

FIG. 14A is a cross sectional view, taken along cut-line A-A′ in FIG. 13A, showing another view of the semiconductor structure at a particular time in the semiconductor fabrication process. In one example embodiment, as depicted by FIG. 14A, the method includes selectively etching the plurality of channel material channels 1437 to form a plurality of first storage node recesses 1453. The first storage node recesses can extend predominantly in the first horizontal direction, from the fifth vertical opening 1449 to a first horizontal distance 1455 from the second pair of nitride lattice support structures 1433-3, 1433-4. In some embodiments the first horizontal distance 1455 can be between 0 nm and 50 nm. FIG. 14A also shows the plurality of channel material channel end portions 1441, gate metal runners 1443, and channel all around gate oxide 1445 between the second pair of nitride lattice support structures 1433-3, 1433-4, surrounded by second sacrificial material 1425, and covered by the nitride well wall 1447.

FIG. 14B is a cross sectional view, taken along cut-line B-B′ in FIG. 13A, showing another view of the semiconductor structure at a particular time in the semiconductor fabrication process. FIG. 14B shows a cross section of the example embodiment along the first lateral direction (D1) 1409 between the first pair of nitride lattice support structures 1433-1, 1433-2 and the second pair of nitride lattice support structures 1433-3, 1433-4. The example embodiment in FIG. 14B illustrates the plurality of first storage node recesses 1453 surrounded by the second sacrificial material 1425, and the nitride well wall 1447 on top of the second sacrificial material 1425.

FIG. 15A is a cross sectional view, taken along cut-line A-A′ in FIG. 13A, showing another view of the semiconductor structure at a particular time in the semiconductor fabrication process. In one example embodiment, as depicted by FIG. 15A, the method includes depositing a first conductive material 1557, such as by low pressure chemical vapor deposition, to fill the plurality of first storage node recesses 1453 and the fifth vertical opening 1449 as seen in FIG. 14A between the first pair of nitride lattice support structures 1533-1, 1533-2, and to contact the remaining plurality of channel material channels 1537. The first conductive material can be a highly n-doped polycrystalline silicon material, or any other suitable material. In alternate embodiments, gas doping/drive in can be used in a contact doping formation process (not shown). FIG. 15A also shows the plurality of channel material channel end portions 1541, gate metal runners 1543, and channel all around gate oxide 1545 between the second pair of nitride lattice support structures 1533-3, 1533-4, surrounded by second sacrificial material 1525, and covered by the nitride well wall 1547.

FIG. 15B is a cross sectional view, taken along cut-line B-B′ in FIG. 13A, showing another view of the semiconductor structure at a particular time in the semiconductor fabrication process. The example embodiment depicted in FIG. 15B shows a cross section of the example embodiment along the first lateral direction (D1) 1509 between the first pair of nitride lattice support structures 1533-1, 1533-2 and the second pair of nitride lattice support structures 1533-3, 1533-4. The example embodiment in FIG. 15B illustrates first conductive material 1557 surrounded by the second sacrificial material 1525, and the nitride well wall on top of the second sacrificial material 1425.

FIG. 16A is a cross sectional view, taken along cut-line A-A′ in FIG. 13A, showing another view of the semiconductor structure at a particular time in the semiconductor fabrication process. In one example embodiment, as depicted by FIG. 16A, the method includes selectively removing a portion of the first conductive material 1657 from the fifth vertical opening 1649 and the plurality of first storage node recesses 1653 between the fifth vertical opening 1649 and a second horizontal distance 1659 from the second pair of nitride lattice support structures 1633-3, 1633-4 to form a contact. In some example embodiments, the first conductive material can be removed through a wet etch process, such as by using Tetramethylammonium hydroxide (TMAH) to etch a highly n-doped poly material, or by other suitable removal process as will be appreciated. In the example embodiment, as depicted by FIG. 16A, the method may further comprise conformally depositing a layer of a second conductive material, (e.g., titanium nitride) such as by atomic layer deposition (ALD), in the fifth vertical opening 1649 and the plurality of first storage node recesses 1653 to form a capacitor bottom electrode 1661. In the example embodiment as depicted by FIG. 16A, the method further comprises selectively recessing the second sacrificial material 1525 surrounding the capacitor bottom electrodes 1661 through the spaces provided by the first pair of nitride lattice support structures 1633-1, 1633-2 to expose both sides of the capacitor bottom electrode 1661 and form a plurality of second storage node recesses 1663 separated from the first storage node recesses 1653 by the capacitor bottom electrode 1661. The capacitor bottom electrode supported by the plurality of nitride lattice support structures 1633. FIG. 16A also shows the plurality of channel material channel end portions 1641, gate metal runners 1643, and channel all around gate oxide 1645 between the second pair of nitride lattice support structures 1633-3, 1633-4, surrounded by second sacrificial material 1625, and covered by the nitride well wall 1647.

FIG. 16B is a cross sectional view, taken along cut-line B-B′ in FIG. 13A, showing another view of the semiconductor structure at a particular time in the semiconductor fabrication process. FIG. 16B illustrates the suspended capacitor bottom electrode 1661 wrapped around a first storage node recess 1653 and surrounded by a second storage node recess 1663 deposited on the second sacrificial lining the first storage node recesses 1653. The capacitor bottom electrode 1661 supported by the plurality of nitride lattice support structures 1633, as shown in FIG. 16A. FIG. 16A also shows the nitride well wall 1647 surrounding the vertical stack 1601.

FIG. 17A is a cross sectional view, taken along cut-line A-A′ in FIG. 13A, showing another view of the semiconductor structure at a particular time in the semiconductor fabrication process. In one example embodiment, as depicted by FIG. 17A, the method includes conformally depositing a capacitor middle insulating material 1765, on the capacitor bottom electrode 1761 in the fifth vertical opening 1749, the plurality of first storage node recesses 1753, and the plurality of second storage node recesses 1763. The capacitor bottom electrode in contact with the first conductive material 1757. FIG. 15A also shows the plurality of channel material channel end portions 1741, gate metal runners 1743, and channel all around gate oxide 1745 between the second pair of nitride lattice support structures 1733-3, 1733-4, surrounded by second sacrificial material 1725, and covered by the nitride well wall 1747.

FIG. 17B is a cross sectional view, taken along cut-line B-B′ in FIG. 13A, showing another view of the semiconductor structure at a particular time in the semiconductor fabrication process. FIG. 17B illustrates the capacitor middle insulating material 1765 disposed on opposing sides of the capacitor bottom electrode 1761. The middle insulating material 1765 and capacitor bottom electrode 1761 can be surrounding the first capacitor recess 1753 and can be surrounded by the second capacitor recess 1763. FIG. 17B also shows nitride well wall 1747 surrounding the vertical stack 1701.

FIG. 18A illustrates an example method, at another stage of a semiconductor fabrication process, for forming arrays of vertically stacked memory cells, having horizontally oriented access devices and vertically oriented access lines, such as illustrated in FIG. 1, and in accordance with a number of embodiments of the present disclosure. FIG. 18A illustrates a top down view of a semiconductor structure at a particular point in time in a semiconductor fabrication process, according to one or more embodiments. In the example embodiment as depicted by FIG. 18A, the method comprises depositing a third conductive material to fill the plurality of first storage node recesses 1753, the second storage node recess 1763, and the fifth vertical opening 1749 to form a double sided capacitor top electrode 1867. In an example embodiment, as depicted by FIG. 18A, the method further comprises opening the digit side to form digit side contact openings 1871, and forming digit side contacts 1869 in the digit side contact openings 1871 through the nitride well wall 1847.

FIG. 18B is a cross sectional view, taken along cut-line A-A′ in FIG. 18A, showing another view of the semiconductor structure at a particular time in the semiconductor fabrication process. FIG. 18B illustrates the double side capacitor top electrode 1867 filling the plurality of first storage node recesses 1753, the second storage node recess 1763, and the fifth vertical opening 1749 as shown in FIG. 17B. The double side capacitor top electrode 1867 can be disposed on both sides of a bottom capacitor electrode 1861 and separated from the bottom capacitor electrode 1861 by a capacitor middle insulating material layer 1865. FIG. 18B also illustrates the gate metal runners 1843 bordering the channel material channel end portions 1841, and the digit side contacts 1869 extending through the digit side contact opening 1871 in the vertical stack 1801 and second sacrificial material 1825 to access the storage nodes through the channel material channel end portions 1841 and first conductive material 1857.

FIG. 18C is a cross sectional view, taken along cut-line B-B′ in FIG. 18A, showing another view of the semiconductor structure at a particular time in the semiconductor fabrication process. FIG. 18C illustrates a cross section of the double sided capacitors. The double sided capacitors having a capacitor top electrode 1867 on both sides of a capacitor bottom electrode 1861, the capacitor top electrode 1867 separated from the capacitor bottom electrode 1861 by a capacitor middle insulating material layer 1865, and the vertical stack 1801 covered by the nitride material well wall 1847.

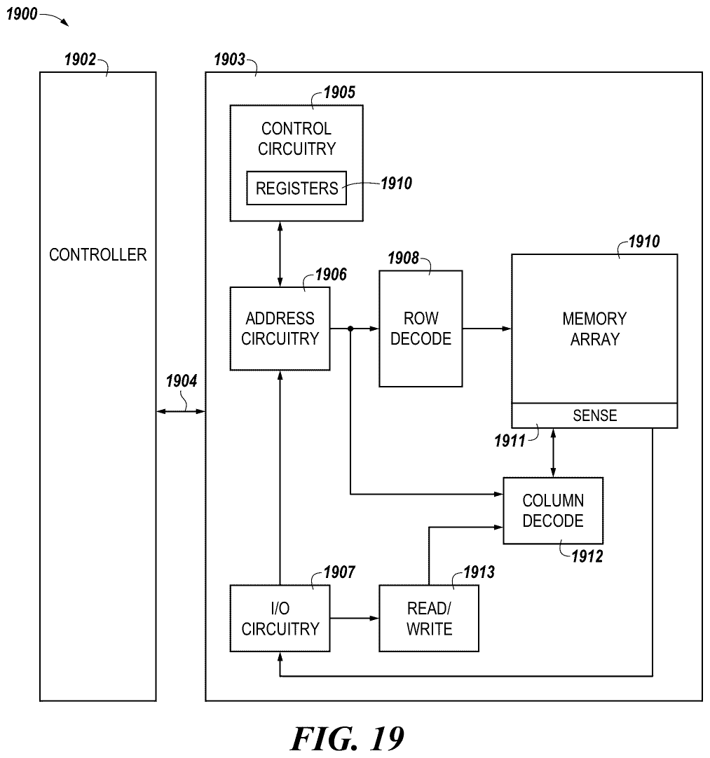

FIG. 19 is a block diagram of an apparatus in the form of a computing system 1900 including a memory device 1903 in accordance with a number of embodiments of the present disclosure. As used herein, a memory device 1903, a memory array 1910, and/or a host 1902, for example, might also be separately considered an “apparatus.” According to embodiments, the memory device 1902 may comprise at least one memory array 1910 having a access device for vertical three-dimensional (3D) memory, as has been described herein.

In this example, system 1900 includes a host 1902 coupled to memory device 103 via an interface 1904. The computing system 1900 can be a personal laptop computer, a desktop computer, a digital camera, a mobile telephone, a memory card reader, or an Internet-of-Things (IoT) enabled device, among various other types of systems. Host 1902 can include a number of processing resources (e.g., one or more processors, microprocessors, or some other type of controlling circuitry) capable of accessing memory 1903. The system 1900 can include separate integrated circuits, or both the host 1902 and the memory device 1903 can be on the same integrated circuit. For example, the host 1902 may be a system controller of a memory system comprising multiple memory devices 1903, with the system controller 1905 providing access to the respective memory devices 1903 by another processing resource such as a central processing unit (CPU).

In the example shown in FIG. 1, the host 1902 is responsible for executing an operating system (OS) and/or various applications (e.g., processes) that can be loaded thereto (e.g., from memory device 1903 via controller 1905). The OS and/or various applications can be loaded from the memory device 1903 by providing access commands from the host 1902 to the memory device 1903 to access the data comprising the OS and/or the various applications. The host 1902 can also access data utilized by the OS and/or various applications by providing access commands to the memory device 1903 to retrieve said data utilized in the execution of the OS and/or the various applications.

For clarity, the system 1900 has been simplified to focus on features with particular relevance to the present disclosure. The memory array 1910 can be a DRAM array, SRAM array, STT RAM array, PCRAM array, TRAM array, RRAM array, NAND flash array, and/or NOR flash array, comprising at least one access device for three dimension (3D) memory. For example, the memory array 1910 can be an unshielded DL 4F2 array such as a 3D-DRAM memory array. The array 1910 can comprise memory cells arranged in rows coupled by word lines (which may be referred to herein as access lines or select lines) and columns coupled by digit lines (which may be referred to herein as sense lines or data lines). Although a single array 1910 is shown in FIG. 1, embodiments are not so limited. For instance, memory device 1903 may include a number of arrays 1910 (e.g., a number of banks of DRAM cells).

The memory device 1903 includes address circuitry 1906 to latch address signals provided over an interface 1904. The interface can include, for example, a physical interface employing a suitable protocol (e.g., a data bus, an address bus, and a command bus, or a combined data/address/command bus). Such protocol may be custom or proprietary, or the interface 1904 may employ a standardized protocol, such as Peripheral Component Interconnect Express (PCIe), Gen-Z, CCIX, or the like. Address signals are received and decoded by a row decoder 1908 and a column decoder 1912 to access the memory array 1910. Data can be read from memory array 1910 by sensing voltage and/or current changes on the sense lines using sensing circuitry 1911. The sensing circuitry 1911 can comprise, for example, sense amplifiers that can read and latch a page (e.g., row) of data from the memory array 1910. The I/O circuitry 1907 can be used for bi-directional data communication with the host 1902 over the interface 1904. The read/write circuitry 1913 can be used to write data to the memory array 1910 or read data from the memory array 1910. As an example, the circuitry 1913 can comprise various drivers, latch circuitry, etc.

Control circuitry 1905 decodes signals provided by the host 1902. The signals can be commands provided by the host 1902. These signals can include chip enable signals, write enable signals, and address latch signals that are used to control operations performed on the memory array 1910, including data read operations, data write operations, and data erase operations. In various embodiments, the control circuitry 1905 can be responsible for executing instructions from the host 1902. The control circuitry 1905 can comprise a state machine, a sequencer, and/or some other type of control circuitry, which may be implemented in the form of hardware, firmware, or software, or any combination of the three. In some examples, the host 1902 can be a controller external to the memory device 103. For example, the host 1902 can be a memory controller which can be coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method for forming a nitride lattice support structure for an array of vertically stacked memory cells having access devices and storage nodes, comprising:
depositing alternating layers of a channel material and a first sacrificial material in repeating iterations to form a vertical stack on a substrate;
patterning the vertical stack to form a plurality of elongated vertical columns having first sidewalls and separated by a plurality of first vertical openings extending predominantly in a first horizontal direction;
depositing a second sacrificial material to fill the first vertical openings and cover the vertical stack;
forming a plurality of second vertical openings through the second sacrificial material, extending predominantly in the first lateral direction across the plurality of first vertical openings,
forming a plurality of third vertical openings extending from each second vertical opening through the second sacrificial material filling the first vertical openings to the substrate to partially expose the first sidewalls of the alternating layers;
selectively etching the first sacrificial material, a first lateral distance back from the plurality third vertical openings to form a plurality of first lateral recesses; and
depositing a nitride material to form a plurality of nitride lattice support structures by filling the plurality of second vertical openings, the plurality of third vertical openings, and the plurality of first lateral recesses.

2. The method of claim 1, wherein patterning the vertical stack includes:
forming a plurality of spaced, first vertical openings through the vertical stack to define elongated vertical columns, adjacent areas where the storage nodes will be formed, with first sidewalls of the alternating layers, the columns having a first lateral direction and a first horizontal direction and extending primarily in the first horizontal direction.

3. The method of claim 1, wherein:
depositing a second sacrificial material to cover the vertical stack includes:
depositing a first oxide material to cover the array and fill the first vertical openings.

4. The method of claim 1, wherein:
the first lateral distance is half of a lateral width of an elongated vertical column of the plurality of elongated vertical columns.

5. The method of claim 1, wherein the third vertical openings extend through alternating occurrences of the first vertical openings, of the plurality of first vertical openings, intersected by a first pair of second vertical openings, the first pair of second vertical openings horizontally disposed adjacent to opposing sides of a storage node electrode exit area.

6. The method of claim 1, wherein the third vertical openings extend through each occurrence of the first vertical openings, of the plurality of first vertical openings, intersected by a second pair of second vertical openings, the second pair of second vertical openings horizontally disposed adjacent opposing sides of where an access device will be formed.

7. The method of claim 1, further comprising:
selectively etching the second sacrificial material to uncover the array and reopen the plurality of first vertical openings; and
selectively etching the first sacrificial material to form a plurality of first horizontal openings to define a plurality of channel material channels supported by the plurality of nitride lattice support structures and extending predominantly in the first horizontal direction.

8. The method of claim 1 further comprising:
depositing a layer of the nitride material on the stacked memory cells to form a nitride well wall, connecting the plurality of nitride lattice support structures.

9. A method for forming an array of vertically stacked memory cells, the array of vertically stacked memory cells comprising:
depositing and patterning alternating layers of a channel material and a first sacrificial material in repeating iterations to form a plurality of elongated vertical columns separated by a plurality of first vertical openings;
depositing a second sacrificial material to cover the vertical stack and fill the first vertical openings;
forming a plurality of second vertical openings;
forming a plurality of third vertical openings;
forming a plurality of first lateral recesses;
depositing a nitride material to form a plurality of nitride lattice support structures;
selectively removing the first sacrificial material and the second sacrificial material to form a plurality of channel material channels;
forming an access device; and
forming cell side contacts and a plurality of storage nodes.

10. The method of claim 9, wherein depositing and patterning alternating layers of the channel material and the first sacrificial material includes:
depositing alternating layers of the channel material and the first sacrificial material in repeating iterations to form a vertical stack; and
forming the plurality of spaced, first vertical openings through the vertical stack to define the plurality of elongated vertical columns, with first sidewalls of the alternating layers, the columns having a first lateral direction and a first horizontal direction and extending primarily in the first horizontal direction.

11. The method of claim 9 wherein forming the plurality of second openings, forming the plurality of third openings, forming the plurality of first lateral recesses, and depositing the nitride material, to form the plurality of nitride lattice support structures includes:
forming the plurality of second vertical openings through the second sacrificial material, extending predominantly in the first lateral direction, and
forming the plurality of third vertical openings, extending predominantly in the first vertical direction, extending from a second vertical opening, of the plurality of second vertical opening, and extending through a first vertical opening, of the plurality of first vertical openings, to partially expose the first sidewalls of the alternating layers, wherein:
the third vertical openings extend through alternating occurrences of the first vertical openings, of the plurality of first vertical openings intersected by a first pair of second vertical openings, the first pair of second vertical openings adjacent, and on either side of a storage node electrode exit area; and
the third vertical openings extend through each first vertical opening, of the plurality of first vertical openings intersected by a second pair of second vertical openings, the second pair of second vertical openings adjacent to, and on either side of, where access devices will be formed;
selectively etching the first sacrificial material, removing the first sacrificial material a first lateral distance back from the third vertical openings to form the plurality of first lateral recesses; and
depositing the nitride material to fill the plurality of second vertical openings, the plurality of third vertical openings, and the plurality of first lateral recesses to form the plurality of nitride lattice support structures.

12. The method of claim 9 wherein selectively removing the first sacrificial material and the second sacrificial material to form the plurality of channel material channels includes:
selectively etching the second sacrificial material to uncover the array and reopen the plurality of first vertical openings; and
selectively etching the first sacrificial material to form a plurality of first horizontal openings to define the plurality of channel material channels extending predominantly in the first horizontal direction.

13. The method of claim 9, wherein forming the access device includes:
depositing additional second sacrificial material to cover the array and fill the plurality of first vertical openings and the plurality of first horizontal openings;
forming a fourth vertical opening through the array extending predominantly in the first lateral direction and positioned between a first nitride lattice support structure, of a second pair of nitride lattice support structures, and a second nitride lattice support structure, of the second pair of nitride lattice support structures, to expose second sidewalls adjacent where access devices will be formed;
selectively etching the second sacrificial material between the first nitride lattice support structure and the second nitride lattice support structure of the second pair of nitride lattice support structures to expose a plurality of channel material channel end portions;
forming a plurality of gate metal runners, the gate metal runners extending primarily in the first lateral direction and wrapping around the plurality of channel material channel end portions; and
depositing additional second sacrificial material between the first nitride lattice support structure and the second nitride lattice support structure of the second pair of nitride lattice support structures to fill the fourth vertical opening and to cover the plurality of channel material channel end portions and the plurality of gate metal runners.

14. The method of claim 9, wherein forming the cell side contacts and the plurality of storage nodes includes:
depositing additional nitride material to form a nitride well wall, disposed on and coupled to the plurality of nitride lattice support structures;
forming a fifth vertical opening, extending predominantly in the first lateral direction, through the array between a first nitride lattice support structure of a first pair of nitride lattice support structures and a second nitride lattice support structure of the first pair of nitride lattice support structures;
selectively removing a portion of the plurality of channel material channels to form a plurality of first storage node recesses, the first storage node recesses extending predominantly in the first horizontal direction, from the fifth vertical opening to a first horizontal distance from a second pair of nitride lattice support structures;
depositing a first conductive material to fill the plurality of first storage node recesses and the fifth vertical opening;
selectively removing the first conductive material from the fifth vertical opening;
selectively removing a portion of the first conductive material from the plurality of first storage node recesses between the fifth vertical opening and a second horizontal distance from the second pair of nitride lattice support structures;
conformally depositing a layer of a second conductive material in the fifth vertical opening and the plurality of first storage node recesses to form a capacitor bottom electrode;
selectively recessing the exposed second sacrificial material to form a plurality of second storage node recesses;
conformally depositing a capacitor middle insulating material layer on the capacitor bottom electrode, in the fifth vertical opening, the plurality of first storage node recesses, and the plurality of second storage node recesses; and
depositing a third conductive material to fill the fifth vertical opening, first storage node recess, and second storage node recess to form a double sided capacitor top electrode.

15. The method of claim 9, wherein a horizontal capacitor of the array has a length of between 0 nm and 150 nm.

16. A memory device, comprising:
an array of vertically stacked memory cells, the array of vertically stacked memory cells having horizontally oriented access devices and horizontally oriented storage nodes, the array of vertically stacked memory cells comprising:
the horizontally oriented access devices having first source/drain regions and second source/drain regions separated by channels, and having gates opposing the channels and separated therefrom by the gate dielectrics;
storage nodes coupled to the second source/drain regions in the array of vertically stacked memory cells; and
a plurality of nitride lattice support structures supporting the horizontally oriented storage devices.

17. The memory device of claim 16, wherein:
the storage nodes are double sided capacitors having a bottom electrode, and a top electrode on either side of the bottom electrode and separated from the bottom electrode by a middle insulating material layer.

18. The memory device of claim 17, wherein:
the plurality of nitride lattice support structures are positioned such that a nitride lattice support structure of the plurality of nitride lattice support structures is horizontally positioned adjacent to, and on either side of, a top electrode exit area and adjacent to, and on either side of, the horizontally oriented access device.

19. The memory device of claim 18 wherein:
the nitride lattice support structures positioned on either side of the source/drain region include a plurality of vertical support structure portions extending vertically down through every second open between each column of the plurality of columns of storage nodes in the array of vertically stacked memory cells.

20. The memory device of claim 18, wherein:
the nitride lattice support structures positioned on either side of the access device area include a plurality of vertical support structure portions extending vertically down through every second opening between each column of the plurality of columns of storage nodes in the array of vertically stacked memory cells.
